(19) United States
(12) Patent Application Publication
(10) Pub. No.: US 2025/0393413 A1
(43) Pub. Date: Dec. 25, 2025

(54) DISPLAY DEVICE INCLUDING A CONNECTION ELECTRODE AND OPTICAL DEVICE

(71) Applicant: SAMSUNG DISPLAY CO., LTD., YONGIN-SI (KR)

(72) Inventor: Hyun Eok SHIN, Yongin-si (KR)

(21) Appl. No.: 19/067,345

(22) Filed: Feb. 28, 2025

(30) Foreign Application Priority Data
Jun. 24, 2024 (KR) 10-2024-0081904

(51) Int. Cl. H10K 59/123; H10K 59/121; H10K 59/124

(52) U.S. Cl. CPC H10K 59/123; H10K 59/1213; H10K 59/124

(57) ABSTRACT

A display device includes a substrate; a plurality of electrodes on the substrate; an insulating film disposed on the plurality of electrodes; a plurality of contact holes penetrating the insulating film and respectively exposing the plurality of electrodes; a trench disposed in the insulating film to overlap the plurality of contact holes; a plurality of connection electrodes respectively connected to the plurality of electrodes through the plurality of contact holes; a pixel electrode connected to at least one of the plurality of connection electrodes; a pixel defining film disposed on the pixel electrode and defining an emission area; a light-emitting layer on the pixel electrode; and a common electrode on the light-emitting layer.

### CROSS-REFERENCE TO RELATED APPLICATION

This application claims priority under 35 U.S.C. 119 from Korean Patent Application No. 10-2024-0081904 filed on Jun. 24, 2024, in the Korean Intellectual Property Office, the disclosure of which in its entirety are herein incorporated by reference.

### BACKGROUND

### 1. Technical Field

The present disclosure relates to a display device and an optical device, and more particularly to a display device including a connection electrode disposed in a trench.

### 2. Discussion of Related Art

An organic light-emitting diode (OLED) display is a self-emissive display type, which typically omits a separate light source. By omitting a separate light source, a thickness and weight of the OLED may be reduced as compared to a liquid crystal display. In addition, an OLED display has garnered attention as a next-generation display for TVs, monitors, and portable electronic devices due to its characteristics such as low power consumption, high luminance, and high response speed.

### SUMMARY

Aspects of the present disclosure provide a display device capable of inhibiting or preventing disconnection of an electrode in a contact hole and an optical device including the same.

According to an embodiment of the present disclosure, there is provided a display device comprising: a substrate; a plurality of electrodes on the substrate; an insulating film disposed on the plurality of electrodes; a plurality of contact holes penetrating the insulating film and respectively exposing the plurality of electrodes; a trench disposed in the insulating film to overlap the plurality of contact holes; a plurality of connection electrodes respectively connected to the plurality of electrodes through the plurality of contact holes; a pixel electrode connected to at least one of the plurality of connection electrodes; a pixel defining film disposed on the pixel electrode and defining an emission area; a light-emitting layer on the pixel electrode; and a common electrode on the light-emitting layer.

According to an embodiment of the present disclosure, there is provided an optical device comprising: a display device; and an optical path changing member above the display device, wherein the display device comprises: a substrate; a plurality of electrodes on the substrate; an insulating film disposed on the plurality of electrodes; a plurality of contact holes penetrating the insulating film and respectively exposing the plurality of electrodes; a trench disposed in the insulating film to overlap the plurality of contact holes; a plurality of connection electrodes respectively connected to the plurality of electrodes through the plurality of contact holes; a pixel electrode connected to at least one of the plurality of connection electrodes; a pixel defining film disposed on the pixel electrode and defining an emission area; a light-emitting layer on the pixel electrode; and a common electrode on the light-emitting layer.

According to an embodiment of the present disclosure, there is provided a display device including a substrate; a plurality of electrodes on the substrate; an insulating film disposed on the plurality of electrodes; a plurality of contact holes penetrating the insulating film and respectively exposing the plurality of electrodes, wherein an inner wall of each contact hole of the plurality of contact holes has a first inclination angle; a trench disposed in the insulating film to overlap the plurality of contact holes, wherein an inner wall of the trench has a second inclination angle; a plurality of connection electrodes respectively connected to the plurality of electrodes through the plurality of contact holes; and a light-emitting element layer disposed on the substrate and connected to at least one of the plurality of connection electrodes.

According to the display device and the optical device of the present disclosure, it is possible to inhibit or prevent disconnection of an electrode in a contact hole.

The effects according to some embodiments of the present disclosure are not limited to those mentioned above and more various effects are included in the following description of the present disclosure.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a perspective view showing a display device according to an embodiment;

FIG. 2 is a cross-sectional view illustrating a display device according to an embodiment;

FIG. 3 is a plan view illustrating a display unit of a display device according to an embodiment;

FIG. 4 is a block diagram illustrating a display panel and a display driver according to an embodiment;

FIG. 5 is a circuit diagram of one pixel of a display device according to an embodiment;

FIG. 6 is a plan view of a unit pixel array according to an embodiment;

FIG. 7 is a plan view selectively showing a first pattern layer of the components of FIG. 6;

FIG. 8 is a plan view selectively showing a second pattern layer of the components of FIG. 6;

FIG. 9 is a plan view selectively showing a third pattern layer of the components of FIG. 6;

FIG. 10 is a plan view selectively showing a fourth pattern layer of the components of FIG. 6;

FIG. 11 is a plan view selectively showing a fifth pattern layer of the components of FIG. 6;

FIG. 12 is a plan view selectively showing a sixth pattern layer of the components of FIG. 6;

FIG. 13 is a plan view selectively showing a seventh pattern layer of the components of FIG. 6;

FIG. 14 is a plan view selectively showing an eighth pattern layer of the components of FIG. 6;

FIG. 15 is a plan view selectively showing first to third pattern layers of the components of FIG. 6;

FIG. 16 is a plan view selectively showing second and third pattern layers of the components of FIG. 6;

FIG. 17 is a plan view selectively showing fourth to sixth pattern layers of the components of FIG. 6;

FIG. 18 is a plan view illustrating connection relationships between second to seventh pattern layers of FIG. 6;

FIG. 19 is a plan view illustrating a connection relationship between seventh and eighth pattern layers of FIG. 6;

FIG. 20 is a plan view illustrating a connection relationship between eighth and ninth pattern layers of FIG. 6;

FIG. 21 is a cross-sectional view taken along line I-I′ of FIG. 6;

FIG. 22 is a plan view of a part of a display device according to an embodiment;

FIG. 23 and FIG. 24 are cross-sectional views taken along line II-II′ of FIG. 22;

FIG. 25 and FIG. 26 are cross-sectional views taken along line III-III′ of FIG. 22;

FIG. 27 is a cross-sectional view of a display device according to an embodiment;

FIG. 28 is a perspective view of the insulating film and the active layer according to an embodiment;

FIG. 29 and FIG. 30 are cross-sectional views taken along line IV-IV′ of FIG. 28;

FIG. 31 and FIG. 32 are cross-sectional views taken along line V-V′ of FIG. 28

FIG. 33 is a cross-sectional view of a display device according to an embodiment;

FIG. 34 is a perspective view illustrating a head mounted display according to an embodiment;

FIG. 35 is an exploded perspective view illustrating an example of the head mounted display of FIG. 34; and

FIG. 36 is a perspective view illustrating a head mounted display according to an embodiment.

FIG. 37 is a block diagram of an electronic device according to one embodiment.

FIGS. 38, 39 and 40 are schematic diagrams of electronic devices according to various embodiments.

### DETAILED DESCRIPTION

The present invention will now be described more fully hereinafter with reference to the accompanying drawings, in which embodiments of the disclosure are shown. Aspects of this disclosure may, however, be embodied in different forms and should not be construed as limited to embodiments set forth herein. Rather, embodiments are provided so that this disclosure will be thorough and complete, and will fully convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions may be exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined in whole or in part. As will be clearly appreciated by those skilled in the art, technically various interactions and operations are possible. Various embodiments can be practiced individually or in combination.

Hereinafter, specific exemplary embodiments will be described with reference to the accompanying drawings.

According to an embodiment, a trench may be disposed in an insulating film, and a connection electrode disposed in the trench may extend through a contact hole to an electrode of a transistor. The contact hole, which is disposed in the trench, may have a reduced height, and a disconnection between the connection electrode and the electrode may be inhibited or prevented.

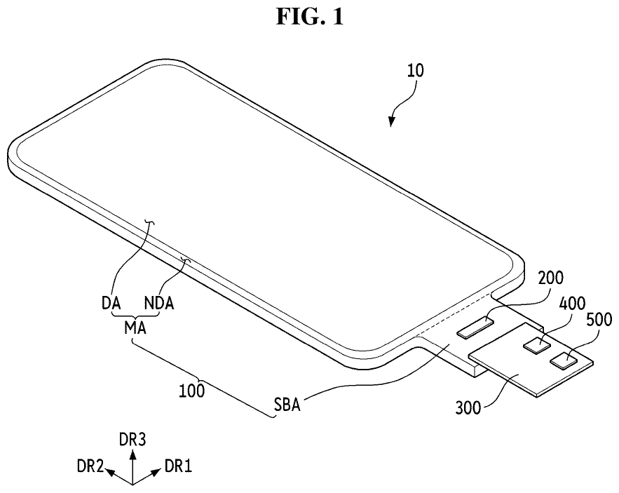

FIG. 1 is a perspective view showing a display device according to an embodiment.

Referring to FIG. 1, a display device 10 may be applied to portable electronic devices such as a mobile phone, a smartphone, a tablet personal computer, a mobile communication terminal, an electronic organizer, an electronic book, a portable multimedia player (PMP), a navigation system, an ultra-mobile PC (UMPC) or the like. For example, the display device 10 may be applied as a display unit of a television, a laptop, a monitor, a billboard, or an Internet-of-Things (IoT) device. For another example, the display device 10 may be applied to wearable devices such as a smart watch, a watch phone, a glasses type display, or a head mounted display (HMD).

The display device 10 may have a planar shape similar to a quadrilateral shape. For example, the display device 10 may have a planar shape similar to a quadrilateral shape having a short side in a first direction DR1 and a long side in a second direction DR2. A corner where the short side in the first direction DR1 and the long side in the second direction DR2 meet may be right-angled or rounded with a predetermined curvature. The planar shape of the display device 10 is not limited to a quadrilateral shape, and may be formed in a shape similar to another polygonal shape, a circular shape, or elliptical shape.

The display device 10 may include a display panel 100, a display driver 200, a circuit board 300, a touch driver 400, and a power supply unit 500.

The display panel 100 may include a main region MA and a sub-region SBA.

The main region MA may include a display area DA including pixels displaying an image and a non-display area NDA disposed around the display area DA. The display area DA may emit light from a plurality of emission areas or a plurality of opening areas. For example, the display panel 100 may include a pixel circuit including switching elements, a pixel defining film defining an emission area or an opening area, and a self-light-emitting element.

For example, the self-light-emitting element may include at least one of an organic light-emitting diode (LED) including an organic light-emitting layer, a quantum dot LED including a quantum dot light-emitting layer, an inorganic LED including an inorganic semiconductor, or a micro LED, but is not limited thereto.

The non-display area NDA may be an area outside the display area DA. The non-display area NDA may be defined as an edge area of the main region MA of the display panel 100. The non-display area NDA may include a gate driver (not illustrated) that supplies gate signals to the gate lines, and fan-out lines (not illustrated) that connect the display driver 200 to the display area DA.

The sub-region SBA may extend from one side of the main region MA. The sub-region SBA may include a flexible material which can be bent, folded or rolled. For example, when the sub-region SBA is bent, the sub-region SBA may overlap the main region MA in a thickness direction (e.g., a third direction DR3). The sub-region SBA may include the display driver 200 and a pad portion connected to the circuit board 300. Optionally, the sub-region SBA may be omitted, and the display driver 200 and the pad portion may be disposed in the non-display area NDA.

The display driver 200 may output signals and voltages for driving the display panel 100. The display driver 200 may supply data voltages to data lines. The display driver 200 may supply a power voltage to the power line and may supply a gate control signal to the gate driver. The display driver 200 may be formed as an integrated circuit (IC) and mounted on the display panel 100 by a chip on glass (COG) method, a chip on plastic (COP) method, or an ultrasonic bonding method. For example, the display driver 200 may be disposed in the sub-region SBA, and may overlap the main region MA in the thickness direction (third direction DR3) by bending of the sub-region SBA. For another example, the display driver 200 may be mounted on the circuit board 300.

The circuit board 300 may be attached to the pad portion of the display panel 100 by using an anisotropic conductive film (ACF). Lead lines of the circuit board 300 may be electrically connected to the pad portion of the display panel 100. The circuit board 300 may be a flexible printed circuit board, a printed circuit board, or a flexible film such as a chip on film.

The touch driver 400 may be mounted on the circuit board 300. The touch driver 400 may be electrically connected to a touch sensing unit of the display panel 100. The touch driver 400 may supply a touch driving signal to a plurality of touch electrodes of the touch sensing unit and may sense an amount of change in capacitance between the plurality of touch electrodes. For example, the touch driving signal may be a pulse signal having a predetermined frequency. The touch driver 400 may calculate whether an input is made and input coordinates based on an amount of change in capacitance between the plurality of touch electrodes. The touch driver 400 may be formed as an integrated circuit (IC).

The power supply unit 500 may be disposed on the circuit board 300 to supply a power voltage to the display driver 200 and the display panel 100. The power supply unit 500 may generate a driving voltage to supply it to a driving voltage line VDL, generate an initialization voltage (e.g., a first initialization voltage and a second initialization voltage) to supply it to an initialization voltage line (e.g., a first initialization voltage line VIL1 and a second initialization voltage line VIL2), and generate a common voltage to supply it to a common electrode which may be common to light-emitting elements of the plurality of pixels. For example, the driving voltage may be a high potential voltage for driving the light-emitting element, and the common voltage may be a low potential voltage for driving the light-emitting element.

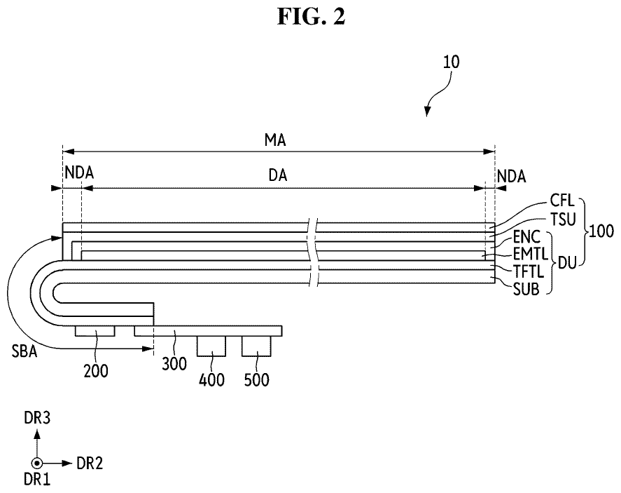

FIG. 2 is a cross-sectional view illustrating a display device according to an embodiment.

Referring to FIG. 2, the display panel 100 may include a display unit DU, a touch sensing unit TSU, and a color filter layer CFL. The display unit DU may include a substrate SUB, a thin film transistor layer TFTL, a light-emitting element layer EMTL, and an encapsulation layer TFEL.

The substrate SUB may be a base substrate or a base member. The substrate SUB may be a flexible substrate which can be bent, folded or rolled. For example, the substrate SUB may include a polymer resin such as polyimide (PI), but is not limited thereto. For another example, the substrate SUB may include a glass material or a metal material.

The thin film transistor layer TFTL may be disposed on the substrate SUB. The thin film transistor layer TFTL may include a plurality of thin film transistors constituting a pixel circuit of pixels. The thin film transistor layer TFTL may further include gate lines, data lines, power lines, gate control lines, fan-out lines that connect the display driver 200 to the data lines, and lead lines that connect the display driver 200 to the pad portion. Each of the thin film transistors may include a semiconductor region, a source electrode, a drain electrode, and a gate electrode. For example, when the gate driver is formed on one side of the non-display area NDA of the display panel 100, the gate driver may include thin film transistors.

The thin film transistor layer TFTL may be disposed in the display area DA, the non-display area NDA, and the sub-region SBA. Thin film transistors, gate lines, data lines, and power lines of each of the pixels of the thin film transistor layer TFTL may be disposed in the display area DA. Gate control lines and fan-out lines of the thin film transistor layer TFTL may be disposed in the non-display area NDA. The lead lines of the thin film transistor layer TFTL may be disposed in the sub-region SBA.

The light-emitting element layer EMTL may be disposed on the thin film transistor layer TFTL. The light-emitting element layer EMTL may include a plurality of light-emitting elements in which a pixel electrode, a light-emitting layer, and a common electrode may be sequentially stacked to emit light, and a pixel defining layer defining pixels. The plurality of light-emitting elements of the light-emitting element layer EMTL may be disposed in the display area DA.

For example, the light-emitting layer may be an organic light-emitting layer including an organic material. The light-emitting layer may include a hole transporting layer, an organic light-emitting layer, and an electron transporting layer. When the pixel electrode receives a predetermined voltage through the thin film transistor of the thin film transistor layer TFTL and the common electrode receives the cathode voltage, holes and electrons may be transferred to the organic light-emitting layer through the hole transporting layer and the electron transporting layer, respectively and may be combined with each other to emit light in the organic light-emitting layer. For example, the pixel electrode may be an anode electrode, and the common electrode may be a cathode electrode, but the present disclosure is not limited thereto.

For another example, the plurality of light-emitting elements may include a quantum dot light-emitting diode including a quantum dot light-emitting layer, an inorganic light-emitting diode including an inorganic semiconductor, or a micro light-emitting diode.

The encapsulation layer ENC may cover the top surface and the side surface of the light-emitting element layer EMTL, and may protect the light-emitting element layer EMTL. The encapsulation layer ENC may include at least one inorganic film and at least one organic film for encapsulating the light-emitting element layer EMTL.

The touch sensing unit TSU may be disposed on the encapsulation layer ENC. The touch sensing unit TSU may include a plurality of touch electrodes for sensing a user's touch in a capacitive manner, and touch lines connecting the plurality of touch electrodes to the touch driver 400. For example, the touch sensing unit TSU may sense the user's touch by using a mutual capacitance method or a self-capacitance method.

For another example, the touch sensing unit TSU may be disposed on a separate substrate disposed on the display unit DU. In this case, the substrate supporting the touch sensing unit TSU may be a base member that encapsulates the display unit DU.

The plurality of touch electrodes of the touch sensing unit TSU may be disposed in a touch sensor area overlapping the display area DA. The touch lines of the touch sensing unit TSU may be disposed in a touch peripheral area that overlaps the non-display area NDA.

The color filter layer CFL may be disposed on the touch sensing unit TSU. The color filter layer CFL may include a plurality of color filters respectively corresponding to the plurality of emission areas. Each of the color filters may selectively transmit light of a specific wavelength and may block or absorb light of a different wavelength. The color filter layer CFL may absorb a part of light coming from the outside of the display device 10 to reduce reflected light due to external light. Accordingly, the color filter layer CFL may inhibit or prevent color distortion that may be caused by reflection of the external light.

Since the color filter layer CFL is directly disposed on the touch sensing unit TSU, the display device 10 may not require a separate substrate for the color filter layer CFL. Therefore, the thickness of the display device 10 may be relatively reduced.

The sub-region SBA of the display panel 100 may extend from a side of the main region MA. The sub-region SBA may include a flexible material which can be bent, folded or rolled. For example, when the sub-region SBA is bent, the sub-region SBA may overlap the main region MA in the thickness direction (third direction DR3). The sub-region SBA may include the display driver 200 and the pad portion electrically connected to the circuit board 300.

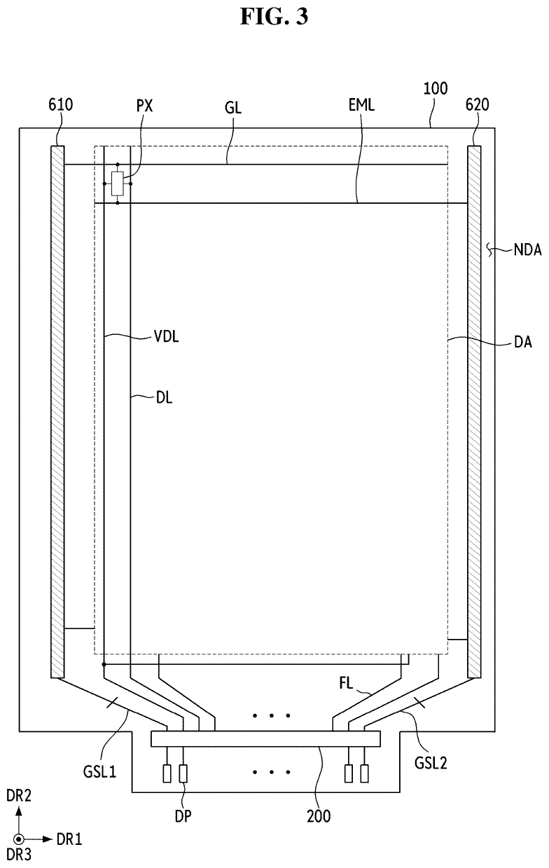

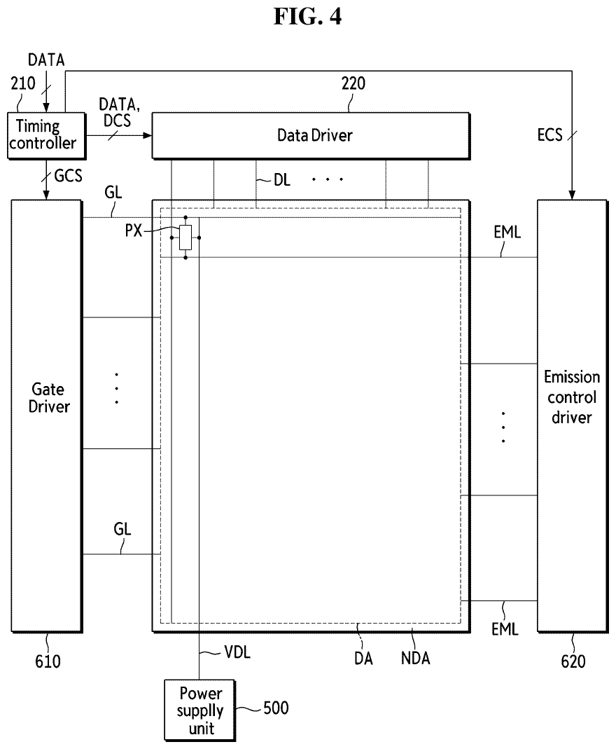

FIG. 3 is a plan view illustrating a display unit of a display device according to an embodiment. FIG. 4 is a block diagram illustrating a display panel and a display driver according to an embodiment.

Referring to FIG. 3 and FIG. 4, the display panel 100 may include the display area DA and the non-display area NDA.

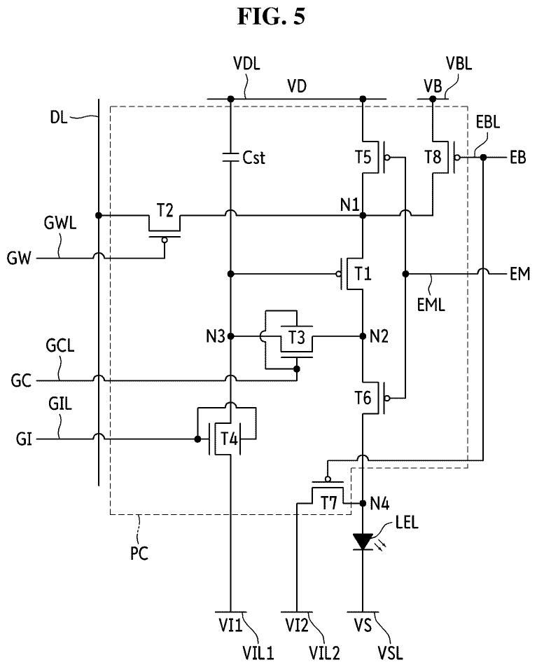

The display area DA may include a plurality of pixels PX, and a plurality of driving voltage lines VDL, a plurality of common voltage lines VSL (see FIG. 5), a plurality of gate lines GL, a plurality of emission control lines EML, and a plurality of data lines DL connected to the plurality of pixels PX.

Each of the plurality of pixels PX may be connected to the gate line GL, the data line DL, the emission control line EML, the driving voltage line VDL, and the common voltage line VSL. Each of the pixels PX may include at least one transistor, a light-emitting element and a capacitor.

Each of the plurality of gate lines GL may extend in the first direction DR1 and may be spaced apart from each other in the second direction DR2 intersecting the first direction DR1. The gate lines GL may be arranged along the second direction DR2. The gate lines GL may sequentially supply gate signals to the plurality of pixels PX.

The emission control lines EML may extend in the first direction DR1 and may be spaced apart from each other in the second direction DR2. The emission control line EML may be arranged along the second direction DR2. The emission control lines EML may sequentially supply an emission control signal to the plurality of pixels PX.

The data lines DL may extend in the second direction DR2 and may be spaced apart from each other in the first direction DR1. The data lines DL may be arranged along the first direction DR1. The data lines DL may supply data voltages to the plurality of pixels PX. The data voltage may determine the luminance of each of the pixels PX.

The driving voltage lines VDL may extend in the second direction DR2 and may be spaced apart from each other in the first direction DR1. The driving voltage lines VDL may be arranged along the first direction DR1. The driving voltage lines VDL may supply a first driving voltage to the plurality of pixels PX. The first driving voltage may be a high potential voltage for driving the light-emitting elements of the pixels PX.

The non-display area NDA may surround the display area DA. The non-display area NDA may include a gate driver 610, an emission control driver 620, fan-out lines FL, a first gate control line GSL1, and a second gate control line GSL2.

The fan-out lines FL may extend from the display driver 200 to the display area DA. The fan-out lines FL may supply the data voltage received from the display driver 200 to the plurality of data lines DL.

The first gate control line GSL1 may extend from the display driver 200 to the gate driver 610. The first gate control line GSL1 may supply a gate control signal GCS received from the display driver 200 to the gate driver 610.

The second gate control line GSL2 may extend from the display driver 200 to the emission control driver 620. The second gate control line GSL2 may supply an emission control signal ECS received from the display driver 200 to the emission control driver 620.

The sub-region SBA may extend from one side of the non-display area NDA. The sub-region SBA may include the display driver 200 and the pad portion DP. The pad portion DP may be disposed closer to one edge of the sub-region SBA than the display driver 200. The pad portion DP may be electrically connected to the circuit board 300 through an anisotropic conductive film (ACF).

The display driver 200 may include a timing controller 210 and a data driver 220.

The timing controller 210 may receive digital video data DATA and timing signals from the circuit board 300. The timing controller 210 may generate, based on the timing signals, a data control signal DCS to control the operation timing of the data driver 220, the gate control signal GCS to control the operation timing of the gate driver 610, and the emission control signal ECS to control the operation timing of the emission control driver 620. The timing controller 210 may supply the gate control signal GCS to the gate driver 610 through the first gate control line GSL1. The timing controller 210 may supply the emission control signal ECS to the emission control driver 620 through the second gate control line GSL2. The timing controller 210 may supply the digital video data DATA and the data control signal DCS to the data driver 220.

The data driver 220 may convert the digital video data DATA into analog data voltages and supply them to the data lines DL through the fan-out lines FL. The gate signals of the gate driver 610 may select the pixels PX to which the data voltage is supplied, and the selected pixels PX may receive the data voltage through the data lines DL.

The power supply unit 500 may be disposed on the circuit board 300 to supply a power voltage to the display driver 200 and the display panel 100. The power supply unit 500 may generate and supply a driving voltage to the driving voltage line VDL, generate and supply an initialization voltage to the initialization voltage line, and generate and supply a common voltage to the common electrode common to the light-emitting elements of the plurality of pixels.

The gate driver 610 may be disposed at one external side of the display area DA or at one side of the non-display area NDA. The emission control driver 620 may be disposed at the other external side of the display area DA or at the other side of the non-display area NDA. However, the present disclosure is not limited thereto. As another example, the gate driver 610 and the emission control driver 620 may be disposed at any one of one side and the other side of the non-display area NDA.

The gate driver 610 may include a plurality of transistors for generating gate signals based on the gate control signal GCS. The emission control driver 620 may include a plurality of transistors for generating emission control signals based on the emission control signal ECS. For example, the transistors of the gate driver 610 and the transistors of the emission control driver 620 may be formed on the same layer as the transistors of each of the pixels PX. The gate driver 610 may supply the gate signals to the gate lines GL, and the emission control driver 620 may supply the emission control signals to the emission control lines EML.

FIG. 5 is a circuit diagram of one pixel of a display device according to an embodiment.

The pixel SP may be connected to a first gate line GWL, a second gate line GCL, a third gate line GIL, a fourth gate line EBL, the emission control line EML, the data line DL, the driving voltage line VDL, a common voltage line VSL, a first initialization voltage line VIL1, a second initialization voltage line VIL2, and a bias voltage line VBL.

The pixel (e.g., PX1) may include a pixel circuit PC and a light-emitting element ED. The pixel circuit PC may include a first transistor T1, a second transistor T2, a third transistor T3, a fourth transistor T4, a fifth transistor T5, a sixth transistor T6, a seventh transistor T7, an eighth transistor T8, and a capacitor Cst.

The first transistor T1 may include a gate electrode, a source electrode, and a drain electrode. The first transistor T1 may control a source-drain current (hereinafter, a driving current) according to the data voltage applied to the gate electrode. The driving current (e.g., Isd) flowing through a channel region of the first transistor T1 may be proportional to the square of a difference between the threshold voltage Vth and the voltage Vsg between the source electrode and the gate electrode of the first transistor T1 (Isd=k×(Vsg−Vth)²). Here, k is a proportional coefficient determined by the structure and physical characteristics of the first transistor T1, Vsg is a source-gate voltage of the first transistor T1, and Vth is a threshold voltage of the first transistor T1.

The light-emitting element ED may emit light by receiving the driving current Isd. The emission amount or the luminance of the light-emitting element ED may be proportional to the magnitude of the driving current Isd.

The light-emitting element ED may be an organic light-emitting diode including a first electrode, a second electrode, and an organic light-emitting layer disposed between the first electrode and the second electrode. For another example, the light-emitting element ED may be an inorganic light-emitting element including a first electrode, a second electrode, and an inorganic semiconductor disposed between the first electrode and the second electrode. For still another example, the light-emitting element ED may be a quantum dot light-emitting element including a first electrode, a second electrode, and a quantum dot light-emitting layer disposed between the first electrode and the second electrode. For still another example, the light-emitting element ED may be a micro light-emitting diode.

The first electrode of the light-emitting element ED may be electrically connected to the fourth node N4. The first electrode of the light-emitting element ED may be connected to the drain electrode of the sixth transistor T6 and the source electrode of the seventh transistor T7 through the fourth node N4. The second electrode of the light-emitting element ED may be connected to the common voltage line VSL. The second electrode of the light-emitting element ED may receive a second driving voltage VS (e.g., a low potential voltage) from the common voltage line VSL.

The second transistor T2 may be turned on by a first gate signal GW of the first gate line GWL to electrically connect the data line DL with a first node N1 that is the source electrode of the first transistor T1. The second transistor T2 may be turned on according to the first gate signal to supply the data voltage to the first node N1. The gate electrode of the second transistor T2 may be electrically connected to the first gate line GWL, the source electrode thereof may be electrically connected to the data line DL, and the drain electrode thereof may be electrically connected to the first node N1.

The third transistor T3 may be turned on by a second gate signal GC of the second gate line GCL to electrically connect the second node N2, which may be the drain electrode of the first transistor T1, to the third node N3, which may be the gate electrode of the first transistor T1. The third transistor T3 may be connected between the third node N3 and the second node N2. For example, the gate electrode of the third transistor T3 may be electrically connected to the second gate line GCL, the source electrode thereof may be electrically connected to the third node N3, and the drain electrode thereof may be electrically connected to the second node. The third transistor T3 may be turned on by a second gate signal of the second gate line GCL to electrically connect the second node N2, which may be the drain electrode of the first transistor T1, to the third node N3, which may be the gate electrode of the first transistor T1. The third transistor T3 may be a double gate transistor having two gate electrodes (e.g., a gate electrode and a counter gate electrode). The gate electrode and the counter gate electrode may be disposed to face each other on different layers.

The fourth transistor T4 may be turned on by a third gate signal GI of the third gate line GIL to electrically connect the third node N3, which may be the gate electrode of the first transistor T1, to the first initialization voltage line VIL1. The fourth transistor T4 may be connected in series between the third node N3 and the first initialization voltage line VIL1. For example, the gate electrode of the fourth transistor T4 may be electrically connected to the third gate line GIL, the source electrode thereof may be electrically connected to the third node N3, and the drain electrode thereof may be electrically connected to the first initialization voltage line VIL1. The fourth transistor T4 may be a double gate transistor. The first initialization voltage line VIL1 may transmit a first initialization voltage VI1.

The fifth transistor T5 may be turned on by an emission control signal EM of the emission control line EML to electrically connect the driving voltage line VDL with the first node N1 that is the source electrode of the first transistor T1. The gate electrode of the fifth transistor T5 may be electrically connected to the emission control line EML, the source electrode thereof may be electrically connected to the driving voltage line VDL, and the drain electrode thereof may be electrically connected to the first node N1.

The sixth transistor T6 may be turned on by the emission control signal EM of the emission control line EML to electrically connect the second node N2 that is the drain electrode of the first transistor T1 with the fourth node N4 that is the first electrode of the light-emitting element ED. The gate electrode of the sixth transistor T6 may be electrically connected to the emission control line EML, the source electrode thereof may be electrically connected to the second node N2, and the drain electrode thereof may be electrically connected to the fourth node N4.

When all of the fifth transistor T5, the first transistor T1, and the sixth transistor T6 are turned on, the driving current may be supplied to the light-emitting element ED.

The seventh transistor T7 may be turned on by a fourth gate signal EB of the fourth gate line EBL to electrically connect the fourth node N4 that is the first electrode of the light-emitting element ED with the second initialization voltage line VIL2. By turning on the seventh transistor T7 based on the fourth gate signal, the first electrode of the light-emitting element ED may be discharged to a second initialization voltage V2. The gate electrode of the seventh transistor T7 may be electrically connected to the fourth gate line EBL, the source electrode thereof may be electrically connected to the fourth node N4, and the drain electrode thereof may be electrically connected to the second initialization voltage line VIL2. The second initialization voltage line VIL2 may transmit a second initialization voltage VI2.

The eighth transistor T8 may be turned on by the fourth gate signal EB of the fourth gate line EBL to electrically connect the bias voltage line VBL with the first node N1 that is the source electrode of the first transistor T1. The eighth transistor T8 may be turned on according to the fourth gate signal to supply a bias voltage VB to the first node N1. The eighth transistor T8 may improve hysteresis of the first transistor T1 by supplying the bias voltage VB to the source electrode of the first transistor T1. The gate electrode of the eighth transistor T8 may be electrically connected to the fourth gate line EBL, the source electrode thereof may be electrically connected to the bias voltage line VBL, and the drain electrode thereof may be electrically connected to the first node N1.

Each of the first transistor T1, the second transistor T2, the fifth transistor T5, the sixth transistor T6, the seventh transistor T7, and the eighth transistor T8 may include a silicon-based active layer. For example, each of the first transistor T1, the second transistor T2, the fifth transistor T5, the sixth transistor T6, the seventh transistor T7, and the eighth transistor T8 may be a p-type transistor including an active layer made of low temperature polycrystalline silicon (LTPS). The active layer made of low temperature polycrystalline silicon may have high electron mobility and excellent turn-on characteristics. Accordingly, in the display device 10, since the transistors having excellent turn-on characteristics are included, it may be possible to stably and efficiently drive the plurality of pixels PX. Each of the first transistor T1, the second transistor T2, the fifth transistor T5, the sixth transistor T6, the seventh transistor T7, and the eighth transistor T8 may output a current flowing into the source electrode to the drain electrode based on a gate low voltage applied to the gate electrode.

The third transistor T3 and the fourth transistor T4 may be n-type transistors including an oxide-based active layer. The transistor including the oxide-based active layer may have a coplanar structure in which a gate electrode is disposed thereon. The transistor including the oxide-based active layer may output a current flowing into the drain electrode to the source electrode based on a gate high voltage applied to the gate electrode.

The capacitor Cst may be electrically connected between the third node N3 that is the gate electrode of the first transistor T1 and the driving voltage line VDL. For example, the first electrode of the capacitor Cst may be electrically connected to the third node N3, and the second electrode of the capacitor Cst may be electrically connected to the driving voltage line VDL, so that a potential difference between the driving voltage line VDL and the gate electrode of the first transistor T1 may be maintained.

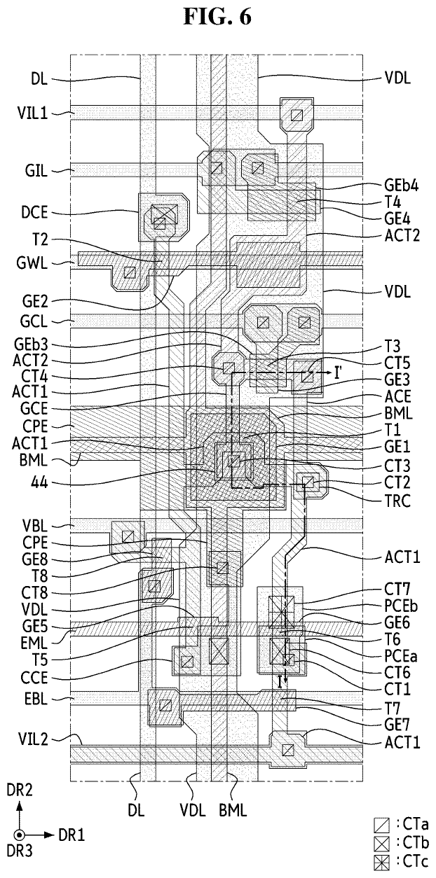

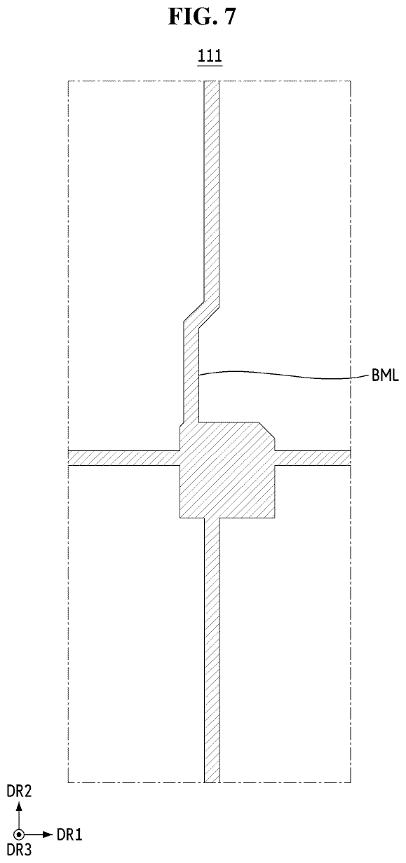

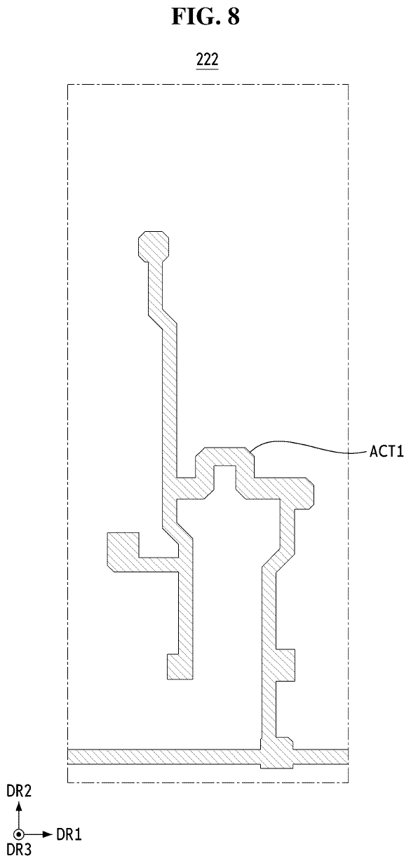

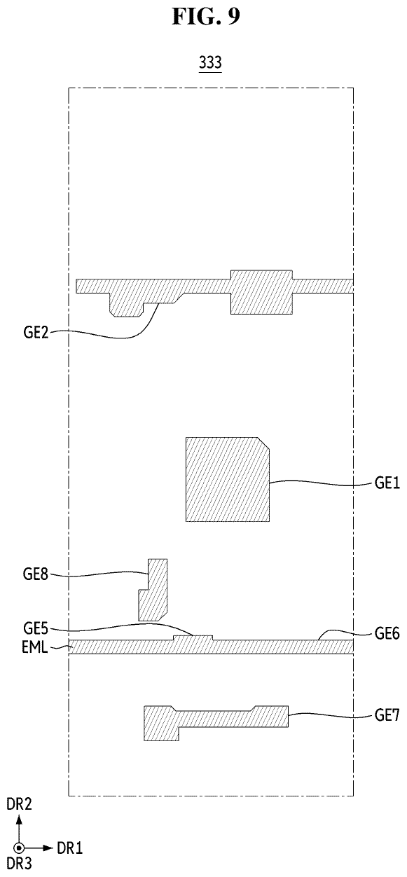

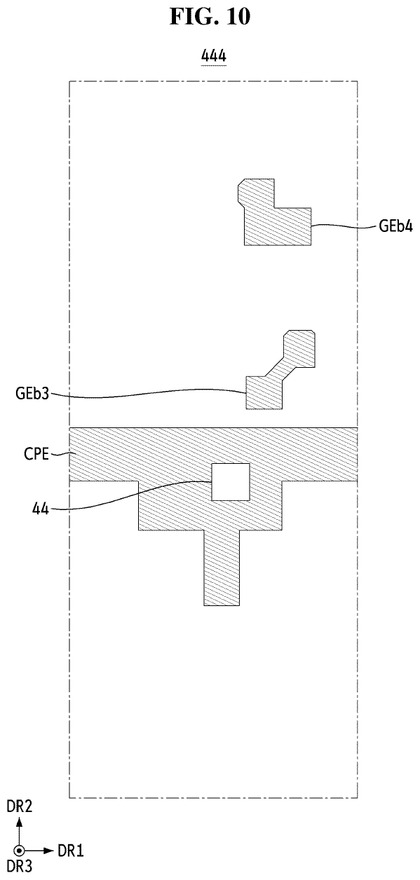

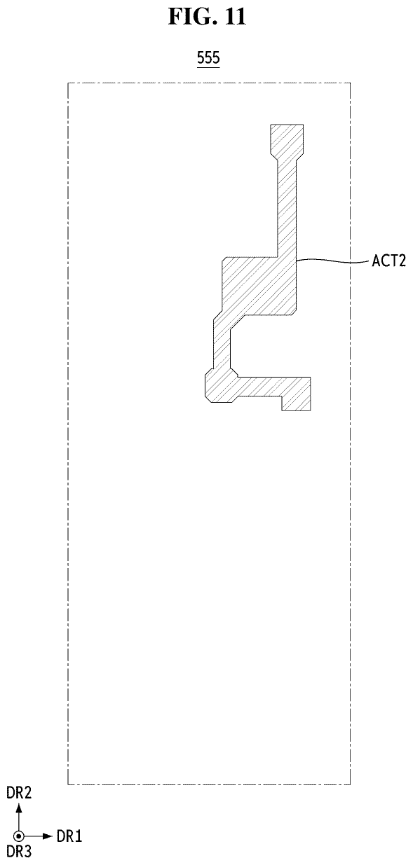

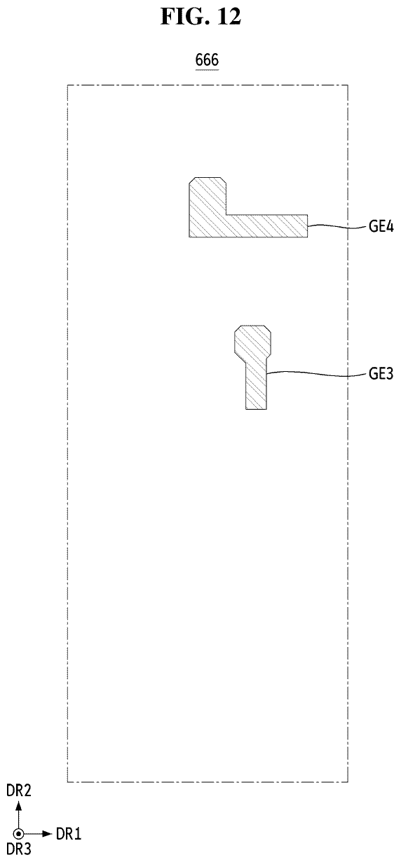

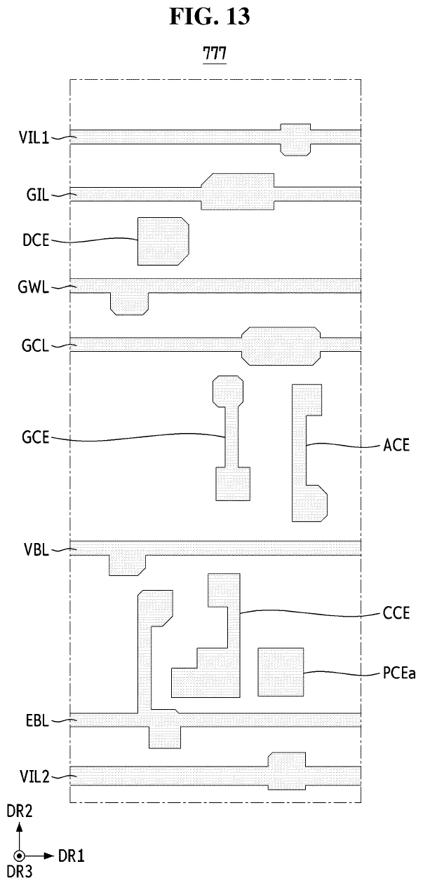

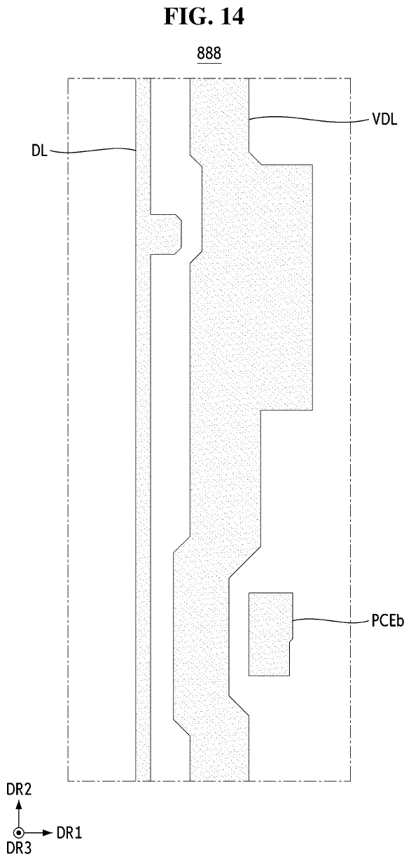

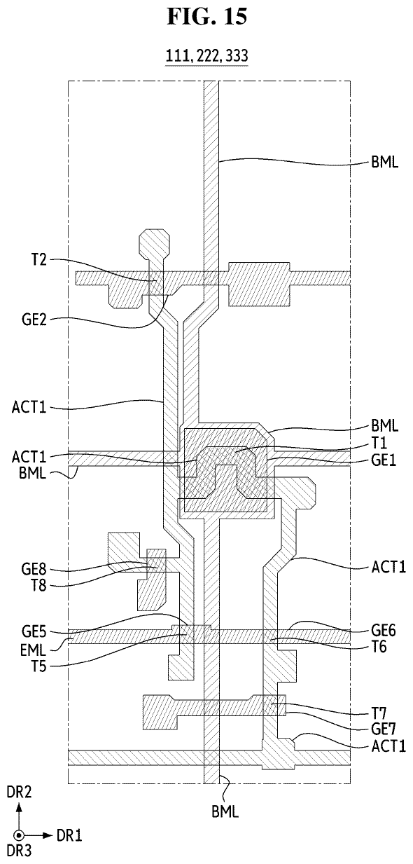

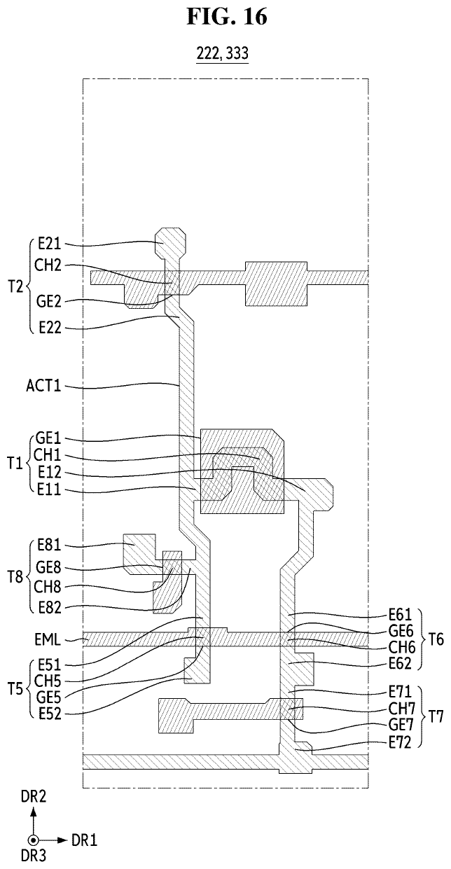

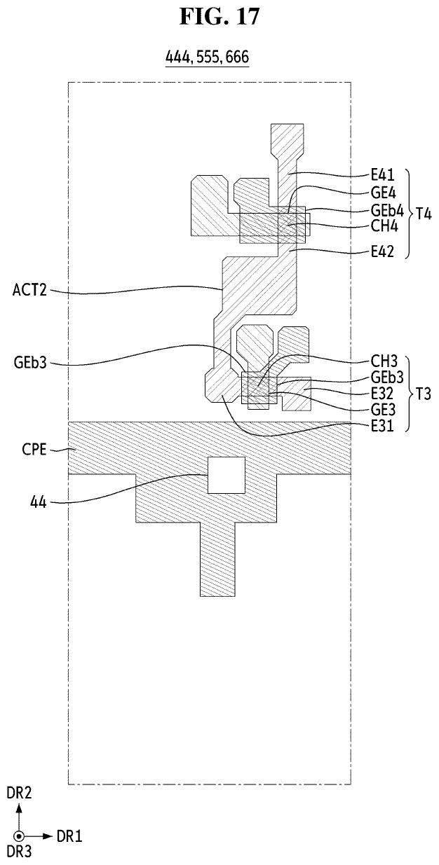

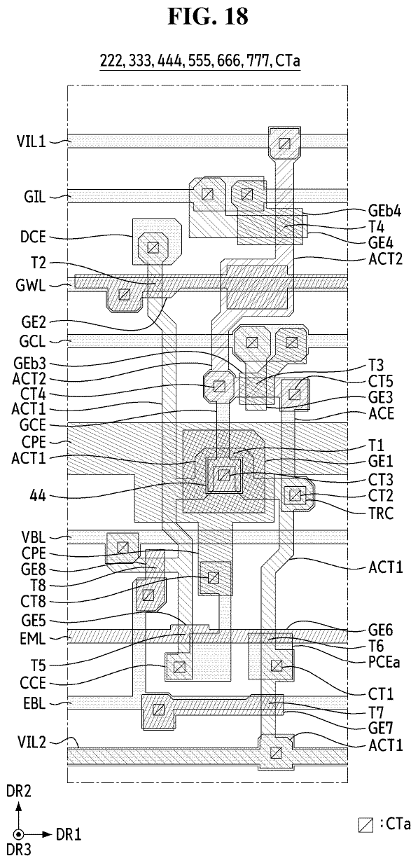

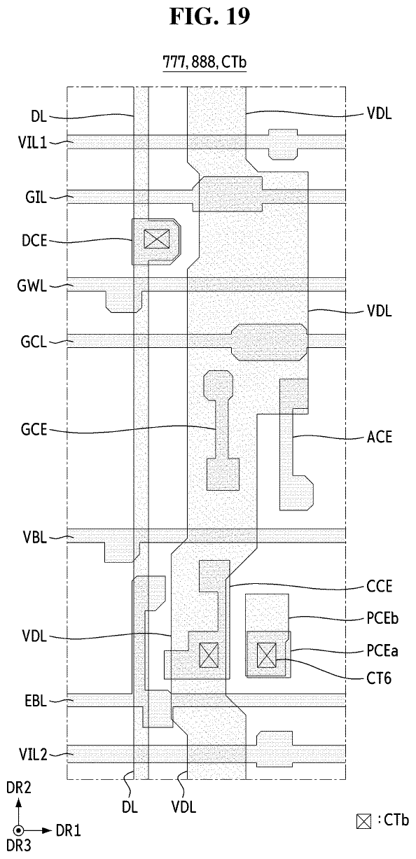

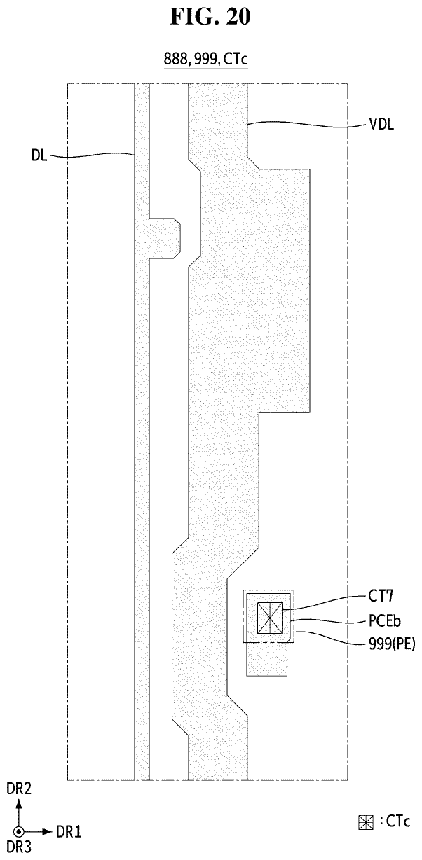

FIG. 6 is a plan view of a unit pixel array according to an embodiment. FIG. 7 is a plan view selectively showing a first pattern layer 111 of the components of FIG. 6. FIG. 8 is a plan view selectively showing a second pattern layer 222 of the components of FIG. 6. FIG. 9 is a plan view selectively showing a third pattern layer 333 of the components of FIG. 6. FIG. 10 is a plan view selectively showing a fourth pattern layer 444 of the components of FIG. 6. FIG. 11 is a plan view selectively showing a fifth pattern layer 555 of the components of FIG. 6. FIG. 12 is a plan view selectively showing a sixth pattern layer 666 of the components of FIG. 6. FIG. 13 is a plan view selectively showing a seventh pattern layer 777 of the components of FIG. 6. FIG. 14 is a plan view selectively showing an eighth pattern layer 888 of the components of FIG. 6. FIG. 15 is a plan view selectively showing first to third pattern layers 111, 222, and 333 of the components of FIG. 6. FIG. 16 is a plan view selectively showing second and third pattern layers 222 and 333 of the components of FIG. 6. FIG. 17 is a plan view selectively showing fourth to sixth pattern layers 444, 555, and 666 of the components of FIG. 6. FIG. 18 is a plan view illustrating connection relationships between second to seventh pattern layers 222 to 777 of FIG. 6. FIG. 19 is a plan view illustrating a connection relationship between seventh and eighth pattern layers 777 and 888 of FIG. 6. FIG. 20 is a plan view illustrating a connection relationship between eighth and ninth pattern layers 888 and 999 of FIG. 6.

Meanwhile, as shown in FIG. 6, contact holes may be classified into a first type contact hole CTa, a second type contact hole CTb, and a third type contact hole CTc. The first type contact hole CTa may be a contact hole for connecting the seventh pattern layer 777 to the pattern layers (e.g., second to sixth pattern layers 222 to 666) therebelow. The second type contact hole CTb may be a contact hole for connecting the eighth pattern layer 888 to the pattern layers (e.g., at least one of the seventh pattern layers 777) therebelow. The third type contact hole CTc may be a contact hole for connecting the ninth pattern layer 999 to the pattern layer (e.g., the eighth pattern layer 888) therebelow.

The first pattern layer 111 may be disposed on the substrate SUB along the third direction DR3. The first pattern layer 111 may include a light blocking layer BML, as in the example shown in FIG. 6, FIG. 7, and FIG. 15.

As shown in FIG. 15, the light blocking layer BML may be disposed on the substrate SUB to cover an overlapping region (e.g., a first channel region CH1) between a first gate electrode GE1 and a first active layer ACT1. In other words, the light blocking layer BML may be disposed on the substrate SUB to overlap the channel region CH1 of the first transistor T1, which may be a driving transistor.

The second pattern layer 222 may be disposed on the first pattern layer 111 along the third direction DR3. The second pattern layer 222 may include the first active layer ACT1, as in the example shown in FIG. 6, FIG. 8, and FIG. 16.

The first active layer ACT1 may provide channel regions CH1, CH2, CH5, CH6, CH7, and CH8, first electrodes E11, E21, E51, E61, E71, and E81, and second electrodes E12, E22, E52, E62, E72, and E82 of the first transistor T1, the second transistor T2, the fifth transistor T5, the sixth transistor T6, the seventh transistor T7, and the eighth transistor T8.

The first active layer ACT1 may be a semiconductor layer made of low temperature polycrystalline silicon (LTPS).

The third pattern layer 333 may be disposed on the second pattern layer 222 along the third direction DR3. An insulating film may be disposed between the second pattern layer 222 and the third pattern layer 333. As in the example shown in FIG. 6, FIG. 9, and FIG. 16, the third pattern layer 333 may include a second gate electrode GE2, the first gate electrode GE1, an eighth gate electrode GE8, the emission control line EML, a fifth gate electrode GE5, a sixth gate electrode GE6, and a seventh gate electrode GE7.

The emission control line EML may include the fifth gate electrode GE5 and the sixth gate electrode GE6. For example, a part of the emission control line EML may correspond to the fifth gate electrode GE5, and another part of the emission control line EML may correspond to the sixth gate electrode GE6. The emission control line EML, the fifth gate electrode GE5, and the sixth gate electrode GE6 may be integrally formed.

The first, second, fifth, sixth, seventh, and eighth gate electrodes GE1, GE2, GE5, GE6, GE7, and GE8 may overlap the first active layer ACT1.

The channel regions CH1, CH2, CH5, CH6, CH7, and CH8 of the first, second, fifth, sixth, seventh, and eighth transistors T1, T2, T5, T6, T7, and T8 may be formed in overlapping regions between the first active layer ACT1 and the first, second, fifth, sixth, seventh, and eighth gate electrodes GE1, GE2, GE5, GE6, GE7, and GE8.

The first transistor T1 may include the first gate electrode GE1, the first electrode E11, the second electrode E12, and a first channel region CH1.

The second transistor T2 may include the second gate electrode GE2, the first electrode E21, the second electrode E22, and a second channel region CH2.

The fifth transistor T5 may include the fifth gate electrode GE5, the first electrode E51, the second electrode E52, and a fifth channel region CH5.

The sixth transistor T6 may include the sixth gate electrode GE6, the first electrode E61, the second electrode E62, and a sixth channel region CH6.

The seventh transistor T7 may include the seventh gate electrode GE7, the first electrode E71, the second electrode E72, and a seventh channel region CH7.

The eighth transistor T8 may include the eighth gate electrode GE8, the first electrode E81, the second electrode E82, and an eighth channel region CH8.

The fourth pattern layer 444 may be disposed on the third pattern layer 333 along the third direction DR3. An insulating film may be disposed between the third pattern layer 333 and the fourth pattern layer 444. As in the example shown in FIG. 6, FIG. 10, FIG. 17, and FIG. 18, the fourth pattern layer 444 may include a fourth counter gate electrode GEb4, a third counter gate electrode GEb3, and a capacitor electrode CPE.

As in the example shown in FIG. 17, the third counter gate electrode GEb3 may overlap a second active layer ACT2 and a third gate electrode GE3. For example, the third counter gate electrode GEb3 may be disposed to face the third gate electrode GE3 with the second active layer ACT2 interposed therebetween.

As in the example shown in FIG. 17, the fourth counter gate electrode GEb4 may overlap the second active layer ACT2 and a fourth gate electrode GE4. For example, the fourth counter gate electrode GEb4 may be disposed to face the fourth gate electrode GE4 with the second active layer ACT2 interposed therebetween.

As shown in FIG. 18, the capacitor electrode CPE may be disposed to overlap the first gate electrode GE1. The capacitor Cst may be formed in a region where the capacitor electrode CPE and the first gate electrode GE1 overlap. For example, the capacitor electrode CPE and the first gate electrode GE1 may correspond to the first electrode and the second electrode of the capacitor Cst, respectively. In addition, the capacitor electrode CPE may have a hole 44 penetrating therethrough in the third direction. The first gate electrode GE1 may be connected to a first electrode E31 of the third transistor T3 through the hole 44 of the capacitor Cst and a gate connection electrode GCE. In addition, the capacitor electrode CPE may be connected to the driving voltage line VDL through a capacitor connection electrode CCE, which will be described later.

The fifth pattern layer 555 may be disposed on the fourth pattern layer 444 along the third direction DR3. An insulating film may be disposed between the fourth pattern layer 444 and the fifth pattern layer 555. The fifth pattern layer 555 may include the second active layer ACT2 as in the example shown in FIG. 6, FIG. 11, FIG. 17 and FIG. 18. The second active layer ACT2 may provide channel regions CH3 and CH4, first electrodes E31 and E41, and second electrodes E32 and E42 of the third and fourth transistors T3 and T4.

The second active layer ACT2 may be, for example, an oxide-based semiconductor.

The sixth pattern layer 666 may be disposed on the fifth pattern layer 555 along the third direction DR3. An insulating film may be disposed between the fifth pattern layer 555 and the sixth pattern layer 666. The sixth pattern layer 666 may include the fourth gate electrode GE4 and the third gate electrode GE3 as in the example shown in FIG. 6, FIG. 12, FIG. 17 and FIG. 18.

As shown in FIG. 17, the third gate electrode GE3 and the fourth gate electrode GE4 may overlap the second active layer ACT2.

The channel regions CH3 and CH4 of the third and fourth transistors T3 and T4 may be formed in overlapping regions between the second active layer ACT2 and the third and fourth gate electrodes GE3 and GE4.

The third transistor T3 may include a third gate electrode GE3, the first electrode E31, the second electrode E32, and a third channel region CH3.

The fourth transistor T4 may include the fourth gate electrode GE4, the first electrode E41, the second electrode E42, and a fourth channel region CH4.

The seventh pattern layer 777 may be disposed on the sixth pattern layer 666 along the third direction DR3. An insulating film may be disposed between the sixth pattern layer 666 and the seventh pattern layer 777. As in the example shown in FIG. 6, FIG. 13, FIG. 18, and FIG. 19, the seventh pattern layer 777 may include the first initialization voltage line VIL1, the third gate line GIL, a data connection electrode DCE, the first gate line GWL, the second gate line GCL, the gate connection electrode GCE, an active connection electrode ACE, the bias voltage line VBL, the capacitor connection electrode CCE, a lower pixel connection electrode PCEa, the fourth gate line EBL, and the second initialization voltage line VIL2.

As shown in FIG. 18, the first initialization voltage line VIL1 may be connected to the first electrode E41 (e.g., the first electrode E41 of the fourth transistor T4) of the second active layer ACT2 through the first type contact hole CTa of the insulating film.

As shown in FIG. 18, the second initialization voltage line VIL2 may be connected to the second electrode E72 (e.g., the second electrode E72 of the seventh transistor T7) of the first active layer ACT1 through the first type contact hole CTa of the insulating film.

As shown in FIG. 18, the first gate line GWL may be connected to the second gate electrode GE2 through the first type contact hole CTa of the insulating film.

As shown in FIG. 18, the second gate line GCL may be connected to the third gate electrode GE3 through the first type contact hole CTa of the insulating film. In addition, the second gate line GCL may be connected to the third counter gate electrode GEb3 through the first type contact hole CTa of the insulating film.

As shown in FIG. 18, the third gate line GIL may be connected to the fourth gate electrode GE4 through the first type contact hole CTa of the insulating film. In addition, the third gate line GIL may be connected to the fourth counter gate electrode GEb4 through the first type contact hole CTa of the insulating film.

As shown in FIG. 18, the fourth gate line EBL may be connected to the seventh gate electrode GE7 through the first type contact hole CTa of the insulating film. In addition, the fourth gate line EBL may be connected to the eighth gate electrode GE8 through the first type contact hole CTa of the insulating film.

As shown in FIG. 18, the gate connection electrode GCE may be connected to the first gate electrode GE1 through the first type contact hole CTa of the insulating film and the hole 44 of the capacitor electrode CPE. Further, the gate connection electrode GCE may be connected to the first electrode E31 (e.g., the first electrode E31 of the third transistor T3) of the second active layer ACT2 and the second electrode E42 (e.g., the second electrode E42 of the fourth transistor T4) of the second active layer ACT2 through the first type contact hole CTa (e.g., CT4) of the insulating film.

As shown in FIG. 18, the data connection electrode DCE may be connected to the first electrode E21 (e.g., the first electrode E21 of the second transistor T2) of the first active layer ACT1 through the first type contact hole CTa of the insulating film.

As shown in FIG. 18, the active connection electrode ACE may be connected to the first electrode E11 (e.g., the first electrode E11 of the first transistor T1) of the first active layer ACT1 through the first type contact hole CTa (e.g., CT2) of the insulating film. Further, the active connection electrode ACE may be connected to the second electrode E32 (e.g., the second electrode E32 of the third transistor T3) of the second active layer ACT2 through the first type contact hole CTa (e.g., CT5) of the insulating film.

As shown in FIG. 18, the lower pixel connection electrode PCEa may be connected to the second electrode E62 (e.g., the second electrode E62 of the sixth transistor T6) of the first active layer ACT through the first type contact hole CTa (e.g., CT1) of the insulating film.

As shown in FIG. 18, the capacitor connection electrode CCE may be connected to the first electrode E51 (e.g., the first electrode E51 of the fifth transistor T5) of the first active layer ACT1 through the first type contact hole CTa of the insulating film. Further, the capacitor connection electrode CCE may be connected to the capacitor electrode CPE through the first type contact hole CTa (e.g., CT8) of the insulating film.

The bias voltage line VBL may transmit the bias voltage VB. As shown in FIG. 18, the bias voltage line VBL may be connected to the first electrode E81 (e.g., the first electrode E81 of the eighth transistor T8) of the first active layer ACT1 through the first type contact hole CTa of the insulating film.

The eighth pattern layer 888 may be disposed on the seventh pattern layer 777 along the third direction DR3. An insulating film may be disposed between the seventh pattern layer 777 and the eighth pattern layer 888. As in the example shown in FIG. 6, FIG. 14, FIG. 19, and FIG. 20, the eighth pattern layer 888 may include a first data line DL, the driving voltage line VDL, and an upper pixel connection electrode PCEb.

As shown in FIG. 19, the first data line DL1 may be connected to the data connection electrode DCE through the second type contact hole CTb of the insulating film.

As shown in FIG. 19, the driving voltage line VDL may be connected to the capacitor connection electrode CCE through the second type contact hole CTb of the insulating film.

As shown in FIG. 19, the upper pixel connection electrode PCEb may be connected to the lower pixel connection electrode PCEa through the second type contact hole CTb (e.g., CT6) of the insulating film.

The ninth pattern layer 999 may be disposed on the eighth pattern layer 888 along the third direction DR3. An insulating film may be disposed between the eighth pattern layer 888 and the ninth pattern layer 999. As in the example shown in FIG. 20, the ninth pattern layer 999 may include a pixel electrode PE. Note that the pixel electrode of FIG. 19 is shown in part, not in its entirety.

A part of the pixel electrode PE may be exposed by a bank (described herein). For example, the bank may have an opening (hereinafter, emission area) through which a part of the pixel electrode PE is exposed. A light-emitting layer may be disposed on the pixel electrode PE corresponding to the emission area.

The pixel electrode PE may be connected to the upper pixel connection electrode PCEb through the third type contact hole CTc (e.g., CT7) of the insulating film.

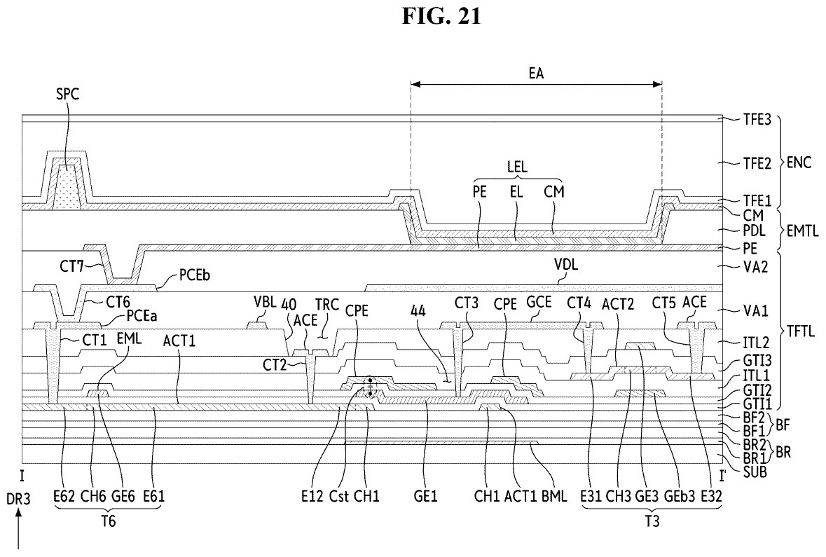

FIG. 21 is a cross-sectional view taken along line I-I′ of FIG. 6.

As illustrated in FIG. 21, the display device 10 may include the substrate SUB, a barrier film BR, the thin film transistor layer TFTL, a light-emitting element layer EMTL, and the encapsulation layer ENC. The barrier film BR, the thin film transistor layer TFTL, the light-emitting element layer EMTL, and the encapsulation layer ENC may be sequentially disposed on the substrate SUB along the third direction DR3.

The substrate SUB may be a rigid substrate or a flexible substrate which can be bent, folded or rolled. The substrate SUB may be formed of an insulating material such as glass, quartz, or a polymer resin. Examples of a polymer material may include polyethersulphone (PES), polyacrylate (PA), polyarylate (PAR), polyetherimide (PEI), polyethylene naphthalate (PEN), polyethylene terephthalate (PET), polyphenylene sulfide (PPS), polyallylate, polyimide (PI), polycarbonate (PC), cellulose triacetate (TAC), cellulose acetate propionate (CAP), or a combination thereof. Alternatively, the substrate SUB may include a metal material.

As shown in FIG. 21, the barrier film BR may be disposed on the substrate SUB. For example, the barrier film BR may be disposed on an upper surface of the substrate SUB. The barrier film BR may be disposed on an entire surface of the substrate SUB. The barrier film BR may be a film for protecting the transistors T1 to T8 of the thin film transistor layer TFTL and a light-emitting layer EL of the light-emitting element layer EMTL. For example, the barrier film BR may be a film for protecting the transistors T1 to T8 of the thin film transistor layer TFTL and a light-emitting layer EL of the light-emitting element layer EMTL from moisture permeating through the substrate SUB, which may be susceptible to moisture permeation.

The barrier film BR may be formed as a plurality of inorganic films that may be alternately stacked. For example, the barrier film BR may be formed of multiple films in which one or more inorganic films of a silicon nitride layer, a silicon oxynitride layer, a silicon oxide layer, a titanium oxide layer or an aluminum oxide layer may be alternately stacked.

As shown in FIG. 21, the first pattern layer 111 may be disposed on the barrier film BR. For example, the light blocking layer BML may be disposed on the barrier film BR. The light blocking layer BML may be disposed on the barrier film BR to cover an overlapping region (e.g., the first channel region CH1) between the first gate electrode GE1 and the first active layer ACT1. In other words, the light blocking layer BML may be disposed on the barrier film BR to overlap the channel region CH1 of the first transistor T1, which may be the driving transistor.

The light blocking layer BML may be made of, for example, a metallic material such as chromium (Cr) or molybdenum (Mo), black ink, black dye, or the like. Meanwhile, when the light blocking layer BML is made of a metallic material, the light blocking layer BML may be supplied with a constant power source. In this way, the light blocking layer BML is not electrically floating, and the transistor (e.g., the first transistor T1) on the light blocking layer BML may have its electrical characteristics stabilized.

As shown in FIG. 21, a buffer film BF may be disposed on the light blocking layer BML. The buffer film BF may be disposed on the entire surface of the substrate SUB including the barrier film BR. The buffer film BF may be a layer for protecting the transistors T1 to T8 of the thin film transistor layer TFTL and a light-emitting layer EL of the light-emitting element layer EMTL. For example, the buffer film BF may be a layer for protecting the transistors T1 to T8 of the thin film transistor layer TFTL and a light-emitting layer EL of the light-emitting element layer EMTL from moisture permeating through the substrate SUB, which may be susceptible to moisture permeation.

The buffer film BF may be formed of a plurality of inorganic films that may be alternately stacked. For example, the buffer film BF may be formed of multiple films in which one or more inorganic films of a silicon nitride layer, a silicon oxynitride layer, a silicon oxide layer, a titanium oxide layer and an aluminum oxide layer may be alternately stacked.

The second pattern layer 222 may be disposed on the buffer film BF. For example, the first active layer ACT1 may be disposed on the barrier film BR. As shown in FIG. 21, the first active layer ACT1 may include the first channel region CH1 of the first transistor T1, the second electrode E12 of the first transistor T1, the first channel region CH1 of the first transistor T1, the first electrode E61 of the sixth transistor T6, the second electrode E62 of the sixth transistor T6, and the sixth channel region CH6 of the sixth transistor T6.

The first active layer ACT1 may be an active layer made of low temperature polycrystalline silicon (LTPS).

A first gate insulating film GTI1 may be disposed on the first pattern layer 111. For example, as shown in FIG. 21, the first gate insulating film GTI1 may be disposed on the first active layer ACT1. In this case, the first gate insulating film GTI1 may be disposed on the entire surface of the substrate SUB including the first active layer ACT1.

The first gate insulating film GTI1 may include at least one of tetraethylorthosilicate (TEOS), silicon nitride (SiNx), or silicon oxide (SiO₂). For example, the first gate insulating film GTI1 may have a double-film structure in which a silicon nitride film having a thickness of about 40 nanometers (nm) and a tetraethylorthosilicate film having a thickness of about 80 nm may be sequentially stacked.

The third pattern layer 333 may be disposed on the first gate insulating film GTI1. For example, the second gate electrode GE2, the first gate electrode GE1, the eighth gate electrode GE8, the emission control line EML, the fifth gate electrode GE5, and the sixth gate electrode GE6 may be disposed on the first gate insulating film GTI1.

FIG. 21 illustrates an example in which the first gate electrode GE1, the sixth gate electrode GE6, and the emission control line EML may be disposed on the first gate insulating film GTI1. The first gate electrode GE1 may be disposed on the first gate insulating film GTI1 to overlap the first channel region CH1 of the first active layer ACT1. The sixth gate electrode GE6 of the emission control line EML may be disposed on the first gate insulating film GTI1 to overlap the sixth channel region CH6 of the first active layer ACT1.

The third pattern layer 333 may include at least one of molybdenum (Mo), copper (Cu), aluminum, or titanium (Ti). The third pattern layer 333 may be formed of a single layer or multiple layers. For example, the first gate electrode GE1 may be formed of a triple film including a titanium film, an aluminum film, and a titanium film disposed sequentially on the first gate insulating film GTI1 along the third direction DR3.

The second gate insulating film GTI2 may be disposed on the third pattern layer 333. For example, as shown in FIG. 21, the second gate insulating film GTI2 may be disposed on the first gate electrode GE1, the sixth gate electrode GE6, and the emission control line EML. In this case, the second gate insulating film GTI2 may be disposed on the entire surface of the substrate SUB including the first gate electrode GE1, the sixth gate electrode GE6, and the emission control line EML.

The second gate insulating film GTI2 may include the same material and structure as the first gate insulating film GTI1 described above.

The fourth pattern layer 444 may be disposed on the second gate insulating film GTI2. For example, the fourth counter gate electrode GEb4, the third counter gate electrode GEb3, and the capacitor electrode CPE may be disposed on the second gate insulating film GTI2. FIG. 21 illustrates an example in which the capacitor electrode CPE and the third counter gate electrode GEb3 may be disposed on the second gate insulating film GTI2. The capacitor electrode CPE may be disposed on the second gate insulating film GTI2 to overlap the first gate electrode GE1. The capacitor Cst may be formed between the capacitor electrode CPE and the first gate electrode GE1.

The fourth pattern layer 333 may have the same material or structure as the third pattern layer 333 described above.

A first interlayer insulating film ITL1 may be disposed on the fourth pattern layer 444. For example, as shown in FIG. 21, the first interlayer insulating film ITL1 may be disposed on the capacitor electrode CPE and the third counter gate electrode GEb3. In this case, the first interlayer insulating film ITL1 may be disposed on the entire surface of the substrate SUB including the capacitor electrode CPE and the third counter gate electrode GEb3.

The first interlayer insulating film ITL1 may include an inorganic film, for example, a silicon nitride layer, a silicon oxynitride layer, a silicon oxide layer, a titanium oxide layer, or an aluminum oxide layer. Meanwhile, the first interlayer insulating film ITL1 may include a plurality of inorganic films.

The fifth pattern layer 555 may be disposed on the first interlayer insulating film ITL1. For example, the second active layer ACT2 may be disposed on the first interlayer insulating film ITL1. As shown in FIG. 21, the second active layer ACT2 may be disposed on the first interlayer insulating film ITL1 to overlap the third counter gate electrode GEb3. The second active layer ACT2 may include the first electrode E31 of the third transistor T3, the second electrode E32 of the third transistor T3, and the third channel region CH3 of the third transistor T3. The third channel region CH3 of the second active layer ACT2 may overlap the third counter gate electrode GEb3.

The second active layer ACT2 may be an oxide-based active layer. For example, the second active layer ACT2 may be an oxide semiconductor containing indium-gallium-zinc oxide (IGZO) or indium-gallium-zinc-tin oxide (IGZTO).

A third gate insulating film GTI3 may be disposed on the fifth pattern layer 555. For example, as shown in FIG. 21, a third gate insulating film GTI3 may be disposed on the second active layer ACT2. The third gate insulating film GTI3 may be disposed on the entire surface of the substrate SUB including the second active layer ACT2.

The third gate insulating film GTI3 may have the same material and structure as the first gate insulating film GTI1 described above.

A sixth pattern layer 666 may be disposed on the third gate insulating film GTI3. For example, the fourth gate electrode GE4 and the third gate electrode GE3 may be disposed on the third gate insulating film GTI3.

FIG. 21 illustrates an example in which the third gate electrode GE3 is disposed on the third gate insulating film GTI3. The third gate electrode GE3 may be disposed to overlap the third channel region CH3 of the second active layer ACT2.

The sixth pattern layer 666 may have the same material or structure as the third pattern layer 333 described above.

A second interlayer insulating film ITL2 may be disposed on the sixth pattern layer 666. For example, as shown in FIG. 21, the second interlayer insulating film ITL2 may be disposed on the third gate electrode GE3. The second interlayer insulating film ITL2 may be disposed on the entire surface of the substrate SUB including the third gate electrode GE3.

The second interlayer insulating film ITL2 may have the same material and structure as the first interlayer insulating film ITL1 described above.

The seventh pattern layer 777 may be disposed on the second interlayer insulating film ITL2. For example, the first initialization voltage line VIL1, the third gate line GIL, the data connection electrode DCE, the first gate line GWL, the second gate line GCL, the gate connection electrode GCE, the active connection electrode ACE, the bias voltage line VBL, the capacitor connection electrode CCE, the lower pixel connection electrode PCEa, the fourth gate line EBL, and the second initialization voltage line VIL2 may be disposed on the second interlayer insulating film ITL2.

FIG. 21 illustrates an example in which the gate connection electrode GCE, the active connection electrode ACE, the bias voltage line VBL, and the lower pixel connection electrode PCEa may be disposed on the second interlayer insulating film ITL2. The lower pixel connection electrode PCEa may be connected to the second electrode E62 of the sixth transistor T6 through a first contact hole CT1 penetrating the second interlayer insulating film ITL2, the third gate insulating film GTI3, the first interlayer insulating film ITL1, the second gate insulating film GTI2, and the first gate insulating film GTI1. The active connection electrode ACE may be connected to the second electrode E12 of the first transistor T1 and the first electrode E61 of the sixth transistor T6 through a trench TRC penetrating the second interlayer insulating film ITL2, and a second contact hole CT2 penetrating the third gate insulating film GTI3, the first interlayer insulating film ITL1, the second gate insulating film GTI2, and the first gate insulating film GTI1. Further, the active connection electrode ACE may be connected to the second electrode E32 of the third transistor T3 through a fifth contact hole CT5 penetrating the second interlayer insulating film ITL2 and the third gate insulating film GTI3. The gate connection electrode GCE may be connected to the first gate electrode GE1 through a third contact hole CT3 penetrating the second interlayer insulating film ITL2, the third gate insulating film GTI3, the first interlayer insulating film ITL1, the hole 44 of the capacitor electrode CPE, and the second gate insulating film GTI2. Further, the gate connection electrode GCE may be connected to the first electrode E31 of the third transistor T3 through a fourth contact hole CT4 penetrating the second interlayer insulating film ITL2 and the third gate insulating film GTI3. The first contact hole CT1, the second contact hole CT2, the third contact hole CT3, the fourth contact hole CT4, and the fifth contact hole CT5 described above may belong to the first type contact hole CTa.

The seventh pattern layer 777 may have the same material or structure as the third pattern layer 333 described above.

A first planarization film VA1 may be disposed on the seventh pattern layer 777. For example, the first planarization film VA1 may be disposed on the gate connection electrode GCE, the active connection electrode ACE, the bias voltage line VBL, and the lower pixel connection electrode PCEa. The first planarization film VA1 may be disposed on the entire surface of the substrate SUB including the gate connection electrode GCE, the active connection electrode ACE, the bias voltage line VBL, and the lower pixel connection electrode PCEa.

The first planarization film VA1 may include an organic film such as acryl resin, epoxy resin, phenolic resin, polyamide resin, polyimide resin and the like.

The eighth pattern layer 888 may be disposed on the first planarization film VA1. For example, the first data line DL1, the driving voltage line VDL, and the upper pixel connection electrode PCEb may be disposed on the first planarization film VA1. FIG. 21 illustrates an example in which the driving voltage line VDL and the upper pixel connection electrode PCEb may be disposed on the first planarization film VA1.

The upper pixel connection electrode PCEb may be connected to the lower pixel connection electrode PCEa through a sixth contact hole CT6 penetrating the first planarization film VA1. The aforementioned sixth contact hole CT6 may belong to the second type contact hole CTb.

The eighth pattern layer 888 may have the same material or structure as the third pattern layer 333 described above.

A second planarization film VA2 may be disposed on the eighth pattern layer 888. For example, the second planarization film VA2 may be disposed on the driving voltage line VDL and the upper pixel connection electrode PCEb. The second planarization film VA2 may be disposed on the entire surface of the substrate SUB including the driving voltage line VDL and the upper pixel connection electrode PCEb.

The second planarization film VA2 may have the same material and structure as the first planarization film VA1 described above.

The ninth pattern layer 999 may be disposed on the second planarization film VA2. For example, as shown in FIG. 21, the light-emitting element layer EMTL including the ninth pattern layer 999 may be disposed on the second planarization film VA2. For example, as shown in FIG. 21, the pixel electrode PE may be disposed on the second planarization film VA2, as the ninth pattern layer 999. The pixel electrode PE may be connected to the upper pixel connection electrode PCEb through a seventh contact hole CT7 penetrating the second planarization film VA2. The aforementioned seventh contact hole CT7 may belong to the third type contact hole CTc.

The light-emitting element layer EMTL described above may further include a light-emitting element LEL and a bank PDL (or pixel defining layer) in addition to the aforementioned ninth pattern layer 999.

The light-emitting element LEL may include the pixel electrode PE, the light-emitting layer EL, and the common electrode CM. An emission area EA, in which the pixel electrode PE, the light-emitting layer EL, and the common electrode CM are sequentially stacked, indicates an area in which holes from the pixel electrode PE and electrons from the common electrode CM may be combined with each other in the light-emitting layer to emit light. In this case, the pixel electrode PE may be the anode electrode of the light-emitting element LEL, and the common electrode CM may be the cathode electrode of the light-emitting element LEL.

In a top emission structure that emits light toward the common electrode CM with respect to the light-emitting layer EL, the pixel electrode PE may be formed of a single layer of molybdenum (Mo), titanium (Ti), copper (Cu), or aluminum (Al), or may be formed to have a stacked structure (Ti/Al/Ti) of aluminum and titanium, a stacked structure (ITO/Al/ITO) of aluminum and ITO, an APC alloy, or a stacked structure (ITO/APC/ITO) of APC alloy and ITO to increase the reflectivity. The APC alloy is an alloy of silver (Ag), palladium (Pd) and copper (Cu).

The bank PDL (or pixel defining layer) may serve to define the emission areas EA of pixels. To this end, the bank PDL may be disposed to expose a part of the pixel electrode PE on the second planarization film VA2. The bank PDL may cover the edge of the pixel electrode PE. Meanwhile, the bank PDL may be disposed in the seventh contact hole CT7 penetrating the second planarization film VA2. Accordingly, the seventh contact hole CT7 penetrating the second planarization film VA2 may be filled with the bank PDL. The bank PDL may be formed of an organic film such as acryl resin, epoxy resin, phenolic resin, polyamide resin, polyimide resin and the like.

As shown in FIG. 21, a spacer SPC may be disposed on the bank PDL. The spacer SPC may serve to support a mask during a process of manufacturing the light-emitting layer EL. The spacer SPC may be formed of an organic film such as acryl resin, epoxy resin, phenolic resin, polyamide resin, polyimide resin and the like.

The light-emitting layer EL may be formed on the pixel electrode PE. The light-emitting layer EL may include an organic material to emit light in a predetermined color. For example, the light-emitting layer EL may include a hole transporting layer, an organic material layer, and an electron transporting layer. The organic material layer may include a host and a dopant. The organic material layer may include a material that emits predetermined light, and may be formed using a phosphorescent material or a fluorescent material.

The aforementioned light-emitting element LEL may be provided for each pixel. For example, a first pixel may include a first light-emitting element, a second pixel may include a second light-emitting element, and a third pixel may include a third light-emitting element. The first light-emitting element, the second light-emitting element, and the third light-emitting element may provide light of different colors. For example, the first light-emitting element may emit light of a first color, the second light-emitting element may emit light of a second color, and the third light-emitting element may emit light of a third color.

For example, the organic material layer of the first light-emitting layer of the first emission area emitting the light of the first color may be a phosphorescent material including a host material including carbazole biphenyl (CBP) or mCP (1,3-bis(carbazol-9-yl), and a dopant including at least one of PIQIr(acac)(bis(1-phenylisoquinoline)acetylacetonate iridium), PQIr(acac)(bis(1-phenylquinoline)acetylacetonate iridium), PQIr(tris(1-phenylquinoline)iridium)) or PtOEP (octacthylporphyrin platinum). Alternatively, the organic material layer of the first light-emitting layer of the first emission area may be a fluorescent material including PBD:Eu(DBM)3(Phen) or Perylene, but the present disclosure is not limited thereto.

The organic material layer of the second light-emitting layer of the second emission area emitting the light of the second color may be a phosphorescent material including a host material including CBP or mCP, and a dopant material including Ir(ppy)3(fac tris(2-phenylpyridinc)iridium. Alternatively, the organic material layer of the second light-emitting layer of the second emission area emitting the light of the second color may be a fluorescent material including tris(8-hydroxyquinolino)aluminum (Alq3), but the present disclosure is not limited thereto.

The organic material layer of the light-emitting layer of the third emission area emitting the light of the third color may be a phosphorescent material including a host material including CBP or mCP, and a dopant material including (4,6-F2ppy)2Irpic or L2BD111, but the present disclosure is not limited thereto.

The common electrode CM may be disposed on the first, second, and third light-emitting layers (e.g., EL). The common electrode CM may be disposed to cover the first, second, and third light-emitting layers. The common electrode CM may be a common layer commonly disposed in the first to third light-emitting layers. A capping layer may be formed on the common electrode CM.

In the top emission structure, the common electrode CM may be formed of a transparent conductive material (TCO) such as ITO or IZO capable of transmitting light or a semi-transmissive conductive material such as magnesium (Mg), silver (Ag), or an alloy of magnesium (Mg) and silver (Ag). When the common electrode CM is formed of a semi-transmissive conductive material, the light emission efficiency can be increased due to a micro-cavity effect.

The encapsulation layer ENC may be formed on the light-emitting element layer EMTL. The encapsulation layer ENC may include at least one inorganic film TFE1 and TFE3 to inhibit or prevent oxygen or moisture from permeating into the light-emitting element layer EMTL. In addition, the encapsulation layer ENC may include at least one organic film to protect the light-emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the common electrode CM, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFEL and the second encapsulation inorganic film TFE3 may be formed of multiple films in which one or more inorganic films of a silicon nitride layer, a silicon oxynitride layer, a silicon oxide layer, a titanium oxide layer and an aluminum oxide layer may be alternately stacked. The encapsulation organic film TFE2 may be an organic film such as acryl resin, epoxy resin, phenolic resin, polyamide resin, or polyimide resin.

According to an embodiment, as shown in FIG. 6, FIG. 18, and FIG. 21, the trench TRC may penetrate the second interlayer insulating film. For example, in cross-sectional view as shown in FIG. 21, the trench TRC may penetrate the second interlayer insulating film in the third direction. The trench TRC and the second contact hole CT2 may be connected to each other.

In plan view as shown in FIG. 6 and FIG. 18, the trench TRC may have a shape surrounding the second contact hole CT2. In other words, in plan view, the inner wall of the trench TRC may have a ring shape surrounding the second contact hole CT2. The trench TRC and the second contact hole CT2 may overlap each other. Further, a portion of a top surface of the insulating film within the trench TRC may surround the second contact hole CT2.

The aforementioned active connection electrode ACE may be disposed in the trench TRC. For example, the active connection electrode ACE may be disposed on the third gate insulating film GTI3 in the trench TRC. Meanwhile, in plan view, when the active connection electrode ACE is larger than the trench TRC, a portion of the active connection electrode ACE may also be disposed on the second interlayer insulating film ITL2. For example, in plan view, when the active connection electrode ACE has a larger size than the trench TRC such that the edge of the active connection electrode ACE surrounds the trench TRC, the edge of the active connection electrode ACE may be disposed on the second interlayer insulating film ITL2.

Due to the trench TRC, the connection path between the active connection electrode ACE and the second electrode E12 of the first transistor T1 may be reduced, and a disconnection of the active connection electrode ACE in the second contact hole CT2 may be inhibited or prevented. Therefore, the active connection electrode ACE and the second electrode E12 of the first transistor T1 may be connected to each other.

According to an embodiment, other contact holes may overlap the trench TRC. For example, the trench TRC penetrating the second interlayer insulating film ITL2 may be further disposed in a region overlapping the first contact hole CT1. In this case, the trench TRC and the first contact hole CT1 may be connected to each other.

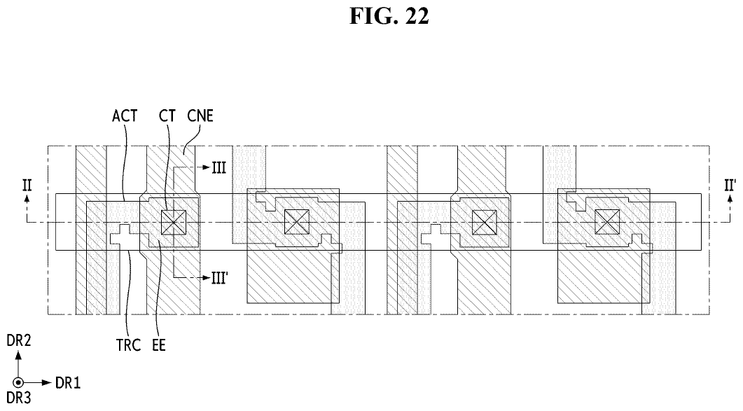

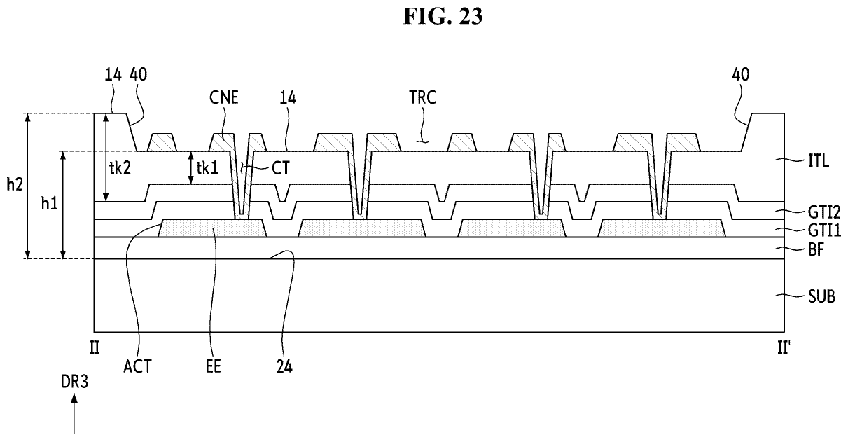

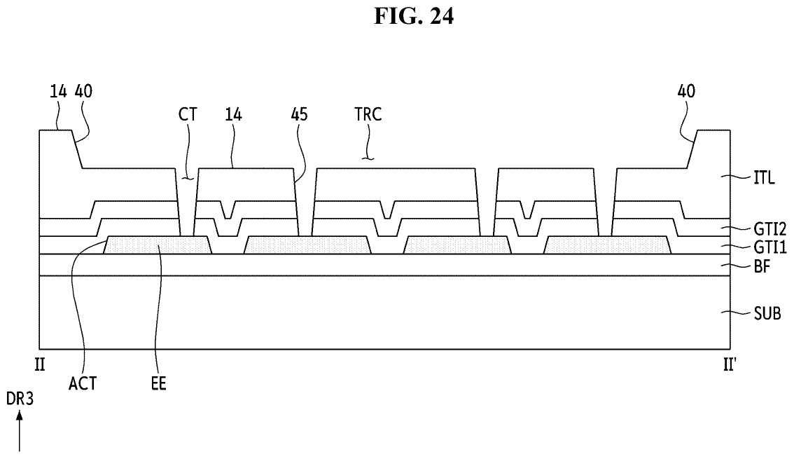

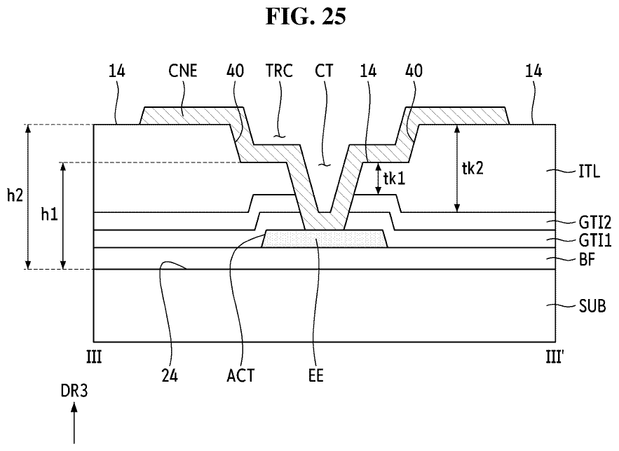

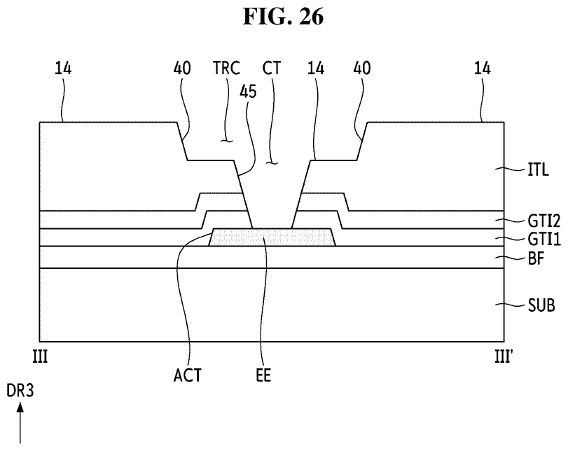

FIG. 22 is a plan view of a part of a display device according to an embodiment, FIG. 23 and FIG. 24 are cross-sectional views taken along line II-II′ of FIG. 22, and FIG. 25 and FIG. 26 are cross-sectional views taken along line III-III′ of FIG. 22. Here, FIG. 24 is a view of FIG. 23 with the connection electrodes CNE omitted, and FIG. 26 is a view of FIG. 25 with the connection electrodes CNE omitted.

As shown in FIGS. 22 to 26, the buffer film BF may be disposed on the substrate SUB, the first gate insulating film GTI1 may be disposed on the buffer film BF, the second gate insulating film GTI2 may be disposed on the first gate insulating film GTI1, and an interlayer insulating film ITL may be disposed on the second gate insulating film GTI2.

The active layer ACT may be disposed on the buffer film BF. The active layer ACT may include an electrode EE.

The trench TRC may be disposed (or formed) on the interlayer insulating film ITL. In this case, the trench TRC may have a groove shape. For example, the trench TRC may have a groove shape recessed toward the substrate SUB (e.g., in the reverse direction of the third direction DR3 (hereinafter, a third reverse direction)). A top surface 14 of the interlayer insulating film ITL may have an uneven shape due to the trench TRC. Accordingly, the interlayer insulating film ITL may have a smaller thickness in a region within the trench TRC. For example, the interlayer insulating film ITL may have a smaller thickness in the region within the trench TRC than in a region outside the trench TRC (tk1<tk2). In other words, a thickness tk1 of the interlayer insulating film ITL in the region within the trench TRC may be smaller than a thickness tk2 of the interlayer insulating film ITL in the region outside the trench TRC.

In addition, as described herein, due to the trench TRC in the interlayer insulating film ITL, the top surface 14 of the interlayer insulating film ITL may be disposed lower in the region within the trench TRC than in the region outside the trench TRC (h1<h2). For example, with respect to a top surface 24 of the substrate SUB, a height h1 of the top surface 14 of the interlayer insulating film ITL in the region within the trench TRC may be smaller than a height h2 of the top surface 14 of the interlayer insulating film ITL in the region outside the trench TRC.

The top surface 14 of the interlayer insulating film ITL may be a horizontal surface. For example, the top surface 14 of the interlayer insulating film ITL may be parallel to an upper surface of the substrate SUB. A first portion of the top surface 14 of the interlayer insulating film ITL within the trench TRC and a second portion of the top surface 14 of the interlayer insulating film ITL outside the trench TRC may each be parallel to the upper surface of the substrate SUB.

The connection electrode CNE may be disposed on the interlayer insulating film ITL. In this case, at least a portion of the connection electrode CNE may be disposed in the trench TRC. The connection electrode CNE may be connected to the electrode of the active layer ACT through the trench TRC and a contact hole CT. For example, the connection electrode CNE may be connected to the electrode EE of the active layer ACT through the contact hole CT penetrating the interlayer insulating film ITL, the second gate insulating film GTI2, and the first gate insulating film GTI1. For example, the contact hole CT penetrating the interlayer insulating film ITL may expose the electrode EE, and the connection electrode CNE may be connected to the electrode EE through the contact hole CT. At least a portion of the connection electrode CNE may be disposed on the top surface 14 of the interlayer within the trench TRC and may surround the contact hole CT.

The contact hole CT may penetrate the interlayer insulating film ITL, the second gate insulating film GTI2, and the first gate insulating film GTI1. For example, the contact hole CT penetrating the interlayer insulating film ITL, the second gate insulating film GTI2, and the first gate insulating film GTI1 may expose the electrode EE The contact hole CT may be disposed to overlap the trench TRC. For example, the top surface 14 of the interlayer within the trench TRC may surround the contact hole CT. In plan view, an inner wall 40 (or edge) of the trench TRC may surround the contact hole CT. The contact hole CT may be connected to the trench TRC.

According to an embodiment, as shown in FIG. 22 and FIG. 23, the plurality of contact holes CT may be disposed in the trench TRC. For example, the trench TRC may have a shape extending in the first direction DR1, and the plurality of contact holes CT may be disposed along the first direction DR1 in the trench TRC. For example, the plurality of contact holes CT may be arranged in a row. At least some of the plurality of connection electrodes CNE may extend in the second direction DR2, and may be perpendicular to the trench TRC. The trench TRC may overlap the plurality of contact holes CT. In plan view, the inner wall 40 (or edge) of the trench TRC may surround all of the plurality of contact holes CT. The trench TRC may be connected to the plurality of contact holes CT.

According to an embodiment, the inner wall 40 (or edge) of the trench TRC may define a portion of the top surface 14 of the insulating film INL, the trench TRC may surround, in plan view, the plurality of contact holes CT, and the plurality of contact holes CT may extend from the portion of the top surface 14 of the insulating film INL, wherein inner walls of the plurality of contact holes CT are spaced apart from the inner wall 40 of the trench TRC.

According to an embodiment, in the display device of FIGS. 22 to 26, the depth of at least one contact hole CT may be greater than the depth of the trench TRC. Here, the depth of the contact hole CT and the depth of the trench TRC may each be a size in the third direction DR3.

According to an embodiment, the depth of the trench TRC may be 0.5 μm.

According to an embodiment, the diameter of the contact hole CT may be about 1.0 micrometers (μm). Here, the diameter of the contact hole CT may be the size of the contact hole CT in the first direction DR1 or the second direction DR2 in plan view.

According to an embodiment, the display device 10 of FIGS. 22 to 26 may further include the second planarization film VA2, the light-emitting element layer EMTL, and the encapsulation layer ENC of FIG. 21 described above. In this case, the second planarization film VA2 may be disposed on the interlayer insulating film ITL and the plurality of connection electrodes CNE, and at least one of the plurality of connection electrodes CNE may be connected to the pixel electrode PE through a contact hole penetrating the second planarization film VA2. In this case, at least one of the plurality of electrodes EE of FIGS. 22 to 26 may be an electrode of a transistor. For example, any one of the plurality of electrodes EE may be the second electrode E62 of the sixth transistor T6.

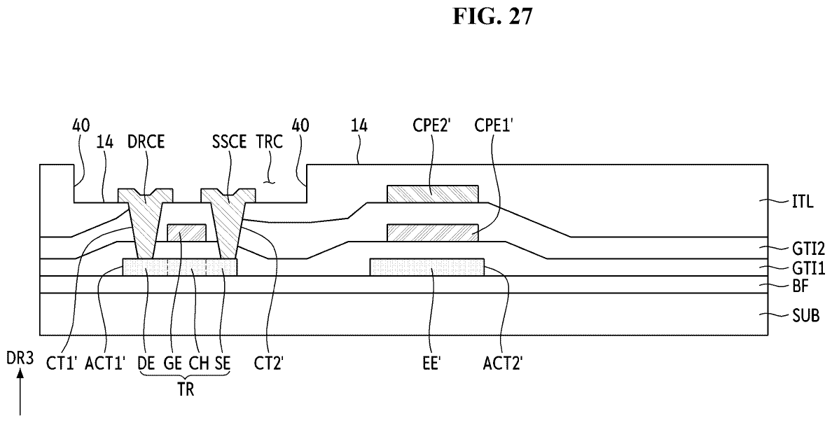

FIG. 27 is a cross-sectional view of a display device according to an embodiment.

As shown in FIG. 27, the buffer film BF may be disposed on the substrate SUB, the first gate insulating film GTI1 may be disposed on the buffer film BF, the second gate insulating film GTI2 may be disposed on the first gate insulating film GTI1, and an interlayer insulating film ITL may be disposed on the second gate insulating film GTI2.

A first active layer ACT1′ and a second active layer ACT2′ may be disposed on the buffer film BF. The first active layer ACT1′ may include a drain electrode DE, a source electrode SE, and a channel region CH. The second active layer ACT2′ may include an electrode EE′.

A gate electrode GE and a first capacitor electrode CPE1′ may be disposed on the first gate insulating film GTI1. For example, the gate electrode GE may be disposed on the first gate insulating film GTI1 to overlap the channel region CH of the first active layer ACT1′, and the first capacitor electrode CPE1′ may be disposed on the first gate insulating film GTI1 to overlap the electrode EE′ of the second active layer ACT2′.

A second capacitor electrode CPE2′ may be disposed on the second gate insulating film GTI2. For example, the second capacitor electrode CPE2′ may be disposed on the second gate insulating film GTI2 to overlap the first capacitor electrode CPE1′. A capacitor may be formed in an overlapping region between the second capacitor electrode CPE2′ and the first capacitor electrode CPE1′.

The trench TRC may be disposed (or formed) in the interlayer insulating film ITL. In this case, the trench TRC may have a groove shape. For example, the trench TRC of the interlayer insulating film ITL may have a groove shape recessed toward the substrate SUB. The top surface 14 of the interlayer insulating film ITL may have an uneven shape due to the trench TRC. Accordingly, the interlayer insulating film ITL may have a smaller thickness in the region within the trench TRC.

In addition, as described above, due to the trench TRC in the interlayer insulating film ITL, the top surface 14 of the interlayer insulating film ITL may be disposed lower in the region within the trench TRC than in the region outside the trench TRC.

A drain connection electrode DRCE and a source connection electrode SSCE may be disposed in the trench TRC. The drain connection electrode DRCE may be connected to the drain electrode DE of the first active layer ACT1′ through the trench TRC and a first contact hole CT1′, and the source connection electrode SSCE may be connected to the source electrode SE of the first active layer ACT1′ through the trench TRC and a second contact hole CT2′.

Since the trench TRC of FIG. 27 is substantially the same as the trench TRC of FIGS. 22 to 26 described herein, a detailed description of the trench TRC of FIG. 27 refers to the description of the trench TRC of FIGS. 22 to 26 described herein, and a repetitive description thereof may be omitted.

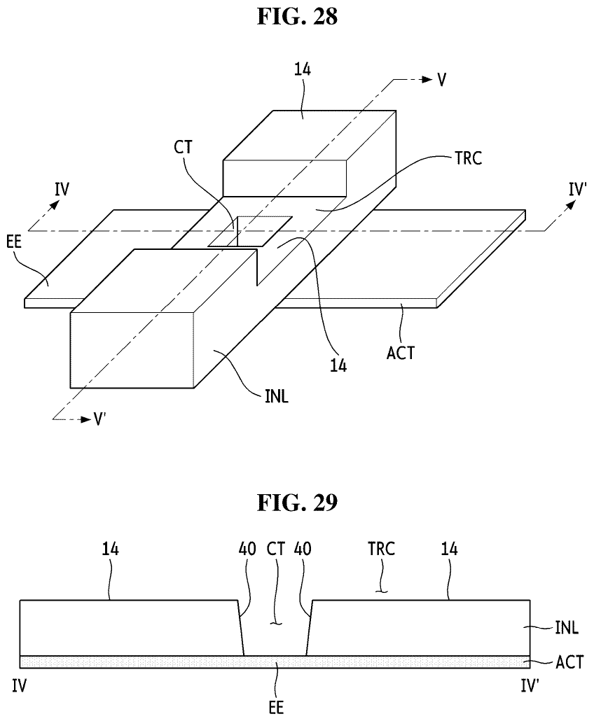

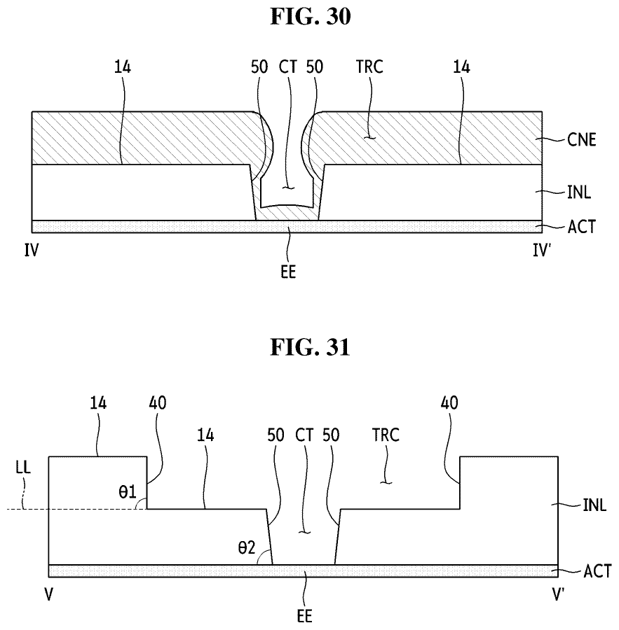

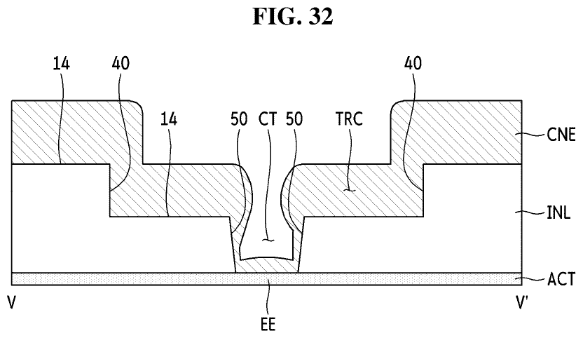

FIG. 28 is a perspective view of the insulating film and the active layer ACT according to an embodiment, FIG. 29 and FIG. 30 are cross-sectional views taken along line IV-IV′ of FIG. 28, and FIG. 31 and FIG. 32 are cross-sectional views taken along line V-V′ of FIG. 28. Here, FIG. 30 is a view of FIG. 29 with a connection electrode further disposed, and FIG. 32 is a view of FIG. 31 with a connection electrode disposed.

As shown in FIGS. 28 to 32, an insulating film INL may be disposed on the active layer ACT.

The active layer ACT may include the electrode EE.

The trench TRC may be disposed (or formed) in the insulating film INL. In this case, the trench TRC may have a groove shape. For example, the trench TRC of the insulating film may have a groove shape recessed toward the substrate SUB. The top surface 14 of the insulating film may have an uneven shape due to the trench TRC. Accordingly, the insulating film INL may have a smaller thickness in the region within the trench TRC.

In addition, as described above, due to the trench TRC of the insulating film INL, the top surface 14 of the insulating film INL may be disposed lower in the region within the trench TRC than in the region outside the trench TRC.

The connection electrode CNE may be disposed on the insulating film INL. In addition, a portion of the connection electrode CNE may be disposed in the trench TRC of the insulating film INL and in the contact hole CT.

The connection electrode CNE may be disposed in the trench TRC. The connection electrode CNE may be connected to the electrode EE of the active layer ACT through the trench TRC and the contact hole CT.

The contact hole CT may penetrate the trench TRC. For example, the contact hole CT may penetrate the insulating film INL in the trench TRC.

Since the trench TRC of FIG. 27 is substantially the same as the trench TRC of FIGS. 22 to 26 described herein, a detailed description of the trench TRC of FIG. 27 refers to the description of the trench TRC of FIGS. 22 to 26 described herein, and a repetitive description thereof may be omitted.

As shown in FIG. 31, an inclination angle θ1 of the inner wall 40 of the trench TRC and an inclination angle θ2 of an inner wall 50 of the contact hole CT may be different. For example, the inclination angle θ1 of the inner wall 40 of the trench TRC, as measured from an imaginary extension plane LL, may be greater than the inclination angle θ2 of the inner wall 50 of the contact hole CT, as measured from the imaginary extension plane LL. Here, the inclination angle θ1 of the inner wall 40 of the trench TRC may be defined as, for example, an angle between the imaginary extension plane LL extending from the top surface 14 of the insulating film INL inside the trench TRC and the inner wall 40 of the trench TRC. In addition, the inclination angle θ2 of the inner wall 50 of the contact hole CT may be defined as, for example, an angle between the active layer ACT and the inner wall 50 of the contact hole CT. Here, the imaginary extension plane LL may be a reference line, and more particularly, a horizontal reference line.

The inclination angle θ2 of the inner wall 50 of the contact hole CT may inhibit or prevent discontinuity of a material disposed in the contact hole CT, which may be due to, for example, a shadow effect. For example, as a material for forming the connection electrodes CNE is disposed in the contact hole CT, the material may overhang a portion of the contact hole CT (see FIG. 32), and in a case that the inner wall 50 of the contact hole CT is inclined or sloped, the portion of connection electrode CNE that may overhang the contact hole CT may not block deposition of the material in a lower portion of the contact hole CT. Further, in a case that a depth of the contact hole CT disposed in the insulating film INL may be reduced by a height of the trench TRC, a discontinuity of a material deposited in the contact hole CT may be further inhibited or prevented.

According to an embodiment, the inner wall 40 of the trench TRC of FIGS. 22 to 26 described above may have the same inclination angle as the inner wall 40 of the trench TRC of FIG. 31, and at least one inner wall 45 of the contact holes CT of FIGS. 22 to 26 may have the same inclination angle as the inner wall 50 of the contact hole CT of FIG. 31.

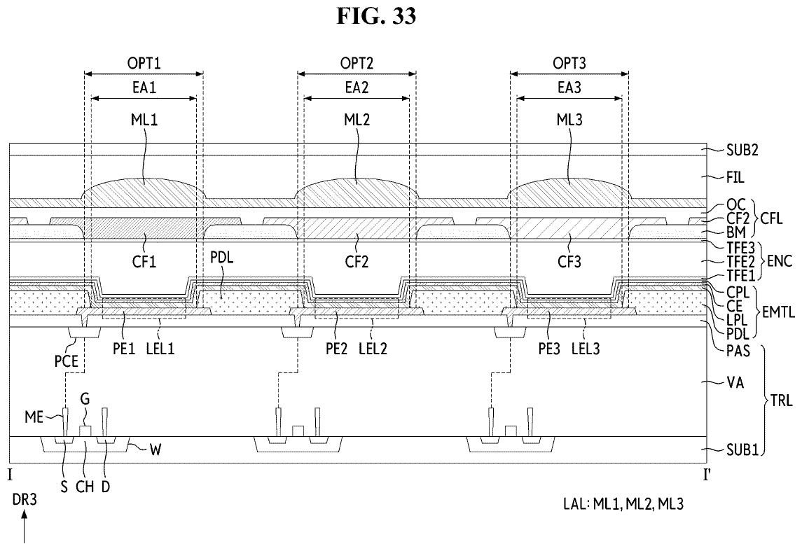

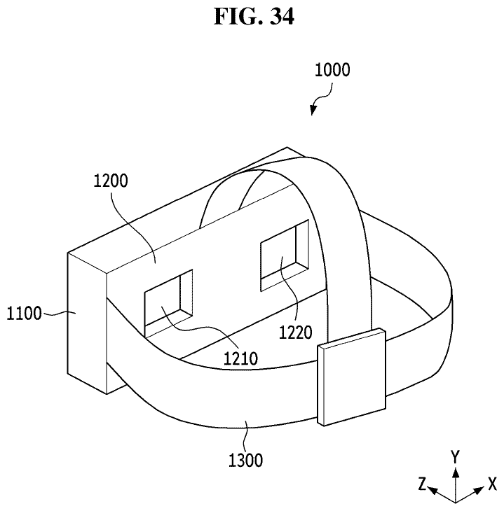

FIG. 33 is a cross-sectional view of a display device according to an embodiment.

As shown in FIG. 33, the display device 10 may include a transistor layer TRL, a light-emitting element layer EMTL, an encapsulation layer ENC, a color filter layer CFL, a lens array layer LAL, and an encapsulation substrate SUB2.

A base substrate SUB1 may be a silicon substrate, a germanium substrate, or a silicon-germanium substrate. The base substrate SUB1 may be a substrate doped with a first type impurity.

A well region W may be disposed on the base substrate SUB1 (or in the base substrate SUB1). The well region W may be a region doped with a second type impurity. The second type impurity may be different from the aforementioned first type impurity. For example, when the first type impurity is a p-type impurity, the second type impurity may be an n-type impurity. Meanwhile, when the first type impurity is an n-type impurity, the second type impurity may be a p-type impurity.

A source region S, a drain region D, and a channel region CH of a transistor TR may be disposed in the well region W. For example, the source region S (or source electrode) and the drain region D (or drain electrode) of the transistor TR may be disposed in the well region W. Each of the source region S and the drain region D may be a region doped with the aforementioned first type impurity. The gate electrode G of the transistor TR may intersect and overlap the well region W. In plan view, the well region W intersecting the gate electrode G may be defined as two parts, and the source region S may be disposed in any one of the two parts, and the drain region D may be disposed in the other part thereof. In other words, in the well region W, the source region S and the drain region D may be disposed on both sides of the gate electrode G with the gate electrode G interposed therebetween. The channel region CH of the transistor may be disposed in the region of the well region W that overlaps the gate electrode G.

Meanwhile, the source region S may include a first low-concentration impurity region having an impurity concentration relatively lower than those of other portions of the source region S. In other words, a portion of the source region S may include a lower concentration of impurities than other portions of the source region S. The drain region D may include a second low-concentration impurity region having an impurity concentration relatively lower than those of other portions of the drain region D. In other words, a portion of the drain region D may include a lower concentration of impurities than other portions of the drain region D.

The first low-concentration impurity region and the second low-concentration impurity region may be disposed close to the channel region CH of the transistor TR. For example, the first low-concentration impurity region may be disposed close to the channel region CH to overlap a first spacer disposed on one side of the gate electrode G, and the second low-concentration impurity region may be disposed close to the channel region CH to overlap a second spacer disposed on the other side of the gate electrode G. In this way, the distance between the high-concentration impurity region of the source region S and the high-concentration impurity region of the drain region D may be increased due to the first low-concentration impurity region and the second low-concentration impurity region, and the length of the channel region CH may be increased due to the increase in the distance. Accordingly, punch-through and hot carrier phenomena caused by a short channel may be inhibited or prevented.

An insulating film VA may be disposed on the base substrate SUB1. The insulating film may include a plurality of insulating films disposed on the base substrate along the third direction. According to an embodiment, the trench TRC and the contact hole described above may be disposed in at least one of the plurality of insulating films. For example, the trench TRC and the contact hole as shown in FIG. 26 may be disposed in any one insulating film.

A passivation film PAS may be disposed on the insulating film VA.

The light-emitting element layer EMTL may be disposed on the passivation film PAS. The light-emitting element layer EMTL may include, for example, a first light-emitting element LEL1, a second light-emitting element LEL2, and a third light-emitting element LEL3 disposed in different emission areas. For example, the first light-emitting element LEL1 of the light-emitting element layer EMTL may be disposed in a first emission area EA1, the second light-emitting element LEL2 of the light-emitting element layer EMTL may be disposed in a second emission area EA2, and the third light-emitting element LEL3 of the light-emitting element layer EMTL may be disposed in a third emission area EA3.

Each of the first light-emitting element LEL1, the second light-emitting element LEL2, and the third light-emitting element LEL3 may provide white light.

The first light-emitting element LEL1 may include a first pixel electrode PE1 (or first anode electrode), a light providing layer LPL, and a common electrode CE stacked in the third direction DR3.

The second light-emitting element LEL2 may include a second pixel electrode PE2 (or second anode electrode), the light providing layer LPL, and the common electrode CE stacked in the third direction DR3.

The third light-emitting element LEL3 may include a third pixel electrode PE3 (or third anode electrode), the light providing layer LPL, and the common electrode CE stacked in the third direction DR3.

Here, the light providing layer LPL and the common electrode CE may be common layers commonly used by the light-emitting elements LEL1 to LEL3. In other words, the plurality of light-emitting elements LEL1 to LEL3 of the light-emitting element layer EMTL may share the light providing layer LPL and the common electrode CE.

The light providing layer LPL may include a plurality of light-emitting layers providing lights of different colors, and the plurality of light-emitting layers may be stacked along the third direction DR3. Different lights from the plurality of light-emitting layers may be mixed to generate white light. Meanwhile, the light providing layer LPL may further include a charge generation layer.

The first pixel electrode PE1, the second pixel electrode PE2, and the third pixel electrode PE3 may be connected to each source region S of each transistor TR through a pixel connection electrode PCE and a metal connection layer ME.

The first pixel electrode PE1 may be disposed to correspond to the first emission area EA1, the second pixel electrode PE2 may be disposed to correspond to the second emission area EA2, and the third pixel electrode PE3 may be disposed to correspond to the third emission area EA3.

A bank PDL (or pixel defining layer) may be disposed on the first pixel electrode PE1, the second pixel electrode PE2, and the third pixel electrode PE3.

The bank PDL may define the emission areas of the pixels (for example, the first emission area EA1 of the first pixel, the second emission area EA2 of the second pixel, and the third emission area EA3 of the third pixel). To this end, the bank PDL may be disposed to expose a partial region of each of the first pixel electrode PE1, the second pixel electrode PE2, and the third pixel electrode PE3 on the passivation film PAS. The bank PDL may cover the edge of each of the first pixel electrode PE1, the second pixel electrode PE2, and the third pixel electrode PE3. The bank PDL may be formed of an organic film such as acryl resin, epoxy resin, phenolic resin, polyamide resin, polyimide resin and the like.

The light providing layer LPL may be disposed on the pixel electrodes PE1, PE2, and PE3 and the bank PDL. For example, the light providing layer LPL may be disposed on the first pixel electrode PE1, the second pixel electrode PE2, the third pixel electrode PE3, and the bank PDL.

The light providing layer LPL may include a plurality of light-emitting units (see FIGS. 13 to 19). For example, the light providing layer LPL may include a first light-emitting unit, a second light-emitting unit, and a third light-emitting unit stacked in the third direction DR3. The light-emitting units may provide lights of different wavelengths. For example, the first light-emitting unit, the second light-emitting unit, and the third light-emitting unit may emit lights of different colors. For example, the light providing layer LPL may have a tandem structure in which the plurality of light-emitting units providing lights of different colors are stacked in a vertical direction (for example, the third direction DR3).

The first light-emitting unit may be disposed on the pixel electrodes PE1, PE2, and PE3. The first light-emitting unit may include a first light-emitting layer, a hole transporting layer, an organic material layer, and an electron transporting layer.

A second light-emitting unit may be disposed on the first light-emitting unit. The second light-emitting unit may include a second light-emitting layer, a hole transporting layer, an organic material layer, and an electron transporting layer.

A third light-emitting unit may be disposed on the second light-emitting unit. The third light-emitting unit may include a third light-emitting layer, a hole transporting layer, an organic material layer, and an electron transporting layer.

The light-emitting elements LEL1, LEL2, and LEL3 may provide white light by mixing light of a first color (for example, blue) from the first light-emitting unit, light of a second color (for example, red) from the second light-emitting unit, and light of a third color (for example, green) from the third light-emitting unit. For example, each of the first light-emitting element LEL1, the second light-emitting element LEL2, and the third light-emitting element LEL3 may provide white light.

Further, the light providing layer LPL may further include at least one charge generation layer in addition to the aforementioned light-emitting units. The charge generation layer may be disposed between the light-emitting units adjacent in the third direction DR3, for example. The charge generation layer may include a first charge generation layer and a second charge generation layer stacked in the third direction, for example. In this case, the first charge generation layer may be disposed between the first light-emitting unit and the second light-emitting unit, and the second charge generation layer may be disposed between the second light-emitting unit and the third light-emitting unit.

On the other hand, each charge generation layer may include a negative charge generation layer and a positive charge generation layer. For example, the first charge generation layer may include a first negative charge generation layer and a first positive charge generation layer stacked in the third direction DR3, and the second charge generation layer may include a second negative charge generation layer and a second positive charge generation layer stacked in the third direction DR3.

The common electrode CE may be disposed on the light providing layer LPL. For example, the common electrode CE may be disposed on the light providing layer LPL to overlap the first pixel electrode PE1, the second pixel electrode PE2, the third pixel electrode PE3, the first emission area EA1, the second emission area EA2, the third emission area EA3, and the bank PDL.

A capping layer CPL may be disposed on the common electrode CE. The capping layer CPL may include an inorganic insulating material. In an exemplary embodiment, the capping layer CPL may include aluminum oxide, titanium oxide, tantalum oxide, hafnium oxide, zinc oxide, silicon oxide, silicon nitride, and/or silicon oxynitride.

The encapsulation layer ENC may be disposed on the capping layer CPL. The encapsulation layer ENC may cover the top surface and the side surface of the light-emitting element layer EMTL, and may protect the light-emitting element layer EMTL. The encapsulation layer ENC may include at least one inorganic film and at least one organic film for encapsulating the light-emitting element layer EMTL. The encapsulation layer ENC may include at least one inorganic film TFE1 and TFE3 to inhibit or prevent oxygen or moisture from permeating into the light-emitting element layer EMTL. In addition, the encapsulation layer ENC may include at least one organic film to protect the light-emitting element layer EMTL from foreign substances such as dust. For example, the encapsulation layer ENC may include a first encapsulation inorganic film TFE1, an encapsulation organic film TFE2, and a second encapsulation inorganic film TFE3.

The first encapsulation inorganic film TFE1 may be disposed on the capping layer CPL, the encapsulation organic film TFE2 may be disposed on the first encapsulation inorganic film TFE1, and the second encapsulation inorganic film TFE3 may be disposed on the encapsulation organic film TFE2. The first encapsulation inorganic film TFE1 and the second encapsulation inorganic film TFE3 may be formed of multiple films in which one or more inorganic films of a silicon nitride layer, a silicon oxynitride layer, a silicon oxide layer, a titanium oxide layer and an aluminum oxide layer are alternately stacked. The encapsulation organic film TFE2 may be an organic film such as acryl resin, epoxy resin, phenolic resin, polyamide resin, or polyimide resin.

A light blocking layer BM may be disposed on the encapsulation layer ENC. The light blocking layer BM may include a plurality of holes OPT1, OPT2, and OPT3 disposed to overlap the emission areas EA1, EA2, and EA3. For example, the first hole OPT1 may be disposed to overlap the first emission area EA1. The second hole OPT2 may be disposed to overlap the second emission area EA2, and the third hole OPT3 may be disposed to overlap the third emission area EA3. The areas or sizes of the holes OPT1, OPT2, and OPT3 may be larger than the areas or sizes of the emission areas EA1, EA2, and EA3 defined by the bank PDL, respectively. The holes OPT1, OPT2, and OPT3 of the light blocking layer BM are formed to be larger than the emission areas EA1, EA2, and EA3, so that the light emitted from the emission areas EA1, EA2, and EA3 may be visually recognized by the user from the front surface and/or from the side surface of the display device 10.

The light blocking layer BM may include a light absorbing material. For example, the light blocking layer BM may include an inorganic black pigment or an organic black pigment. The inorganic black pigment may be carbon black, and the organic black pigment may include at least one of lactam black, perylene black, or aniline black, but they are not limited thereto. The light blocking layer BM may inhibit or prevent visible light infiltration and color mixture between the first to third emission areas EA1, EA2, and EA3, which leads to the improvement of color reproducibility of the display device 10.

The display device 10 may include the plurality of color filters CF1, CF2, and CF3 disposed on the emission areas EA1, EA2, and EA3. The plurality of color filters CF1, CF2, and CF3 may be disposed to correspond to the emission areas EA1, EA2, and EA3, respectively. For example, the color filters CF1, CF2, and CF3 may be disposed on the light blocking layer BM including the plurality of holes OPT1, OPT2, and OPT3 disposed to correspond to the emission areas EA1, EA2, and EA3, respectively.

The color filters CF1, CF2, and CF3 may include a first color filter CF1, a second color filter CF2, and a third color filter CF3 disposed to correspond to the different emission areas EA1, EA2, and EA3, respectively. The color filters CF1, CF2, and CF3 may include a colorant such as a dye or a pigment that absorbs light in a wavelength band other than a specific wavelength band, and may be disposed to correspond to the color of the light emitted from the emission areas EA1, EA2, and EA3. For example, the first color filter CF1 may be a red color filter that is disposed to overlap the first emission area EA1 and transmits the first light of the red color. The second color filter CF2 may be a green color filter that is disposed to overlap the second emission area EA2 and transmits the second light of the green color, and the third color filter CF3 may be a blue color filter that is disposed to overlap the third emission area EA3 and transmits the third light of the blue color.

The plurality of color filters CF1, CF2, and CF3 may be spaced apart from other adjacent color filters CF1, CF2, and CF3 on the light blocking layer BM. The color filters CF1, CF2, and CF3 may have areas larger than those of the holes OPT1, OPT2, and OPT3 of the light blocking layer BM, respectively, while covering the holes, and may have areas enough to be spaced apart from other color filters CF1, CF2, and CF3 on the light blocking layer BM. However, the present disclosure is not limited thereto. The plurality of color filters CF1, CF2, and CF3 may be disposed to partially overlap other adjacent color filters CF1, CF2, and CF3. The different color filters CF1, CF2, and CF3 are areas that do not overlap the emission areas EAI, EA2, and EA3, and may overlap each other on the light blocking layer BM. In the display device 10, the color filters CF1, CF2, and CF3 are disposed to overlap each other, so that the intensity of the reflected light by external light may be reduced. Furthermore, the color of the reflected light by the external light may be controlled by adjusting the disposition, shape, and area of the color filters CF1, CF2, and CF3 in plan view.

An overcoat layer OC may be disposed on the color filters CF1, CF2, and CF3 to planarize the top end portions of the color filters CF1, CF2, and CF3. The overcoat layer OC may be a colorless light transmissive layer that does not have a color in a visible light band. For example, the overcoat layer OC may include a colorless light transmissive organic material such as an acrylic resin.

The lens array layer LAL may be disposed on the overcoat layer OC. The lens array layer LAL may include a plurality of micro lenses ML1, ML2, and ML3. For example, the lens array layer LAL may include a first micro lens ML1 disposed to correspond to the first emission area EA1 or a first hole OPT1, a second micro lens ML2 disposed to correspond to the second emission area EA2 or a second hole OPT2, and a third micro lens ML3 disposed to correspond to the third emission area EA3 or a third hole OPT3.

The micro lenses ML1, ML2, and ML3 may have sizes larger than those of the corresponding holes OPT1, OPT2, and OPT3. For example, the micro lenses ML1, ML2, and ML3 may completely cover the corresponding holes OPT1, OPT2, and OPT3 and may overlap a part of the light blocking layer BM. Since the micro lenses ML1, ML2, and ML3 are formed to be larger than the holes OPT1, OPT2, and OPT3 of the light blocking layer BM, lights emitted from the emission areas EA1, EA2, and EA3 may be recognized by a user from the side surface as well as the front surface of the display device 10.

A filler FIL may be disposed on the lens array layer LAL. The filler FIL may be disposed between adjacent micro lenses.

The encapsulation substrate SUB2 may be disposed on the filler FIL.

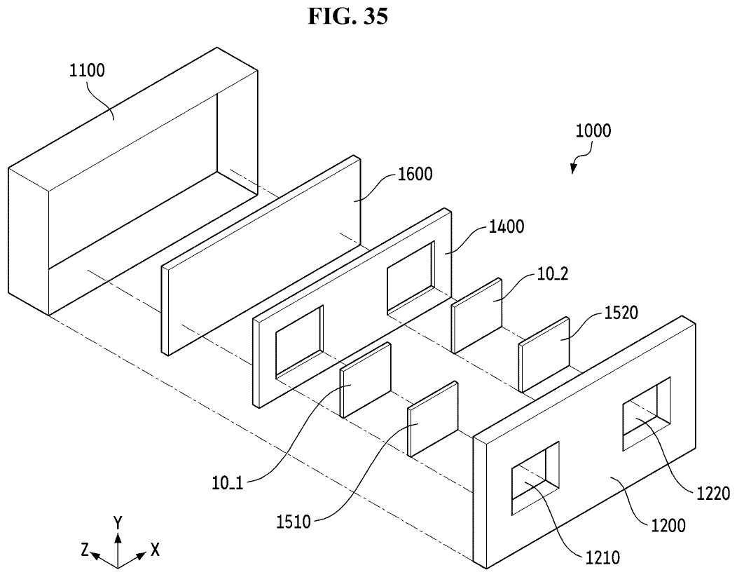

FIG. 34 is a perspective view illustrating a head mounted display according to an embodiment. FIG. 35 is an exploded perspective view illustrating an example of the head mounted display of FIG. 34.

Referring to FIG. 34 and FIG. 35, a head mounted display 1000 according to an embodiment includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Since each of the first display device 10_1 and the second display device 10_2 is substantially the same as the display device 10 described in conjunction with FIGS. 1 to 33, the description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 serves to support and fix the first display device 10_1, the second display device 10_2, and the control circuit board 1600.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA, and transmit the digital video data DATA to the first display device 10_1 and the second display device 10_2 through the connector.

The control circuit board 1600 may transmit the digital video data DATA corresponding to a left-eye image optimized for the user's left eye to the first display device 10_1, and may transmit the digital video data DATA corresponding to a right-eye image optimized for the user's right eye to the second display device 10_2. Alternatively, the control circuit board 1600 may transmit the same digital video data DATA to the first display device 10_1 and the second display device 10_2.

The display device housing 1100 serves to accommodate the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at which the user's left eye is located and the second eyepiece 1220 at which the user's right eye is located. FIG. 34 and FIG. 35 illustrate that the first eyepiece 1210 and the second eyepiece 1220 are disposed separately, but embodiments of the present disclosure is not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

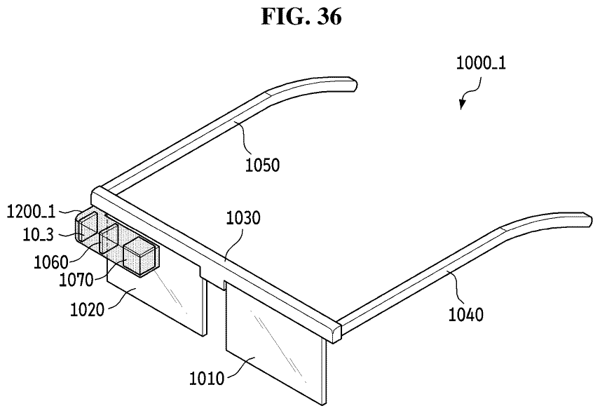

The head mounted band 1300 serves to secure the display device housing 1100 to the user's head such that the first eyepiece 1210 and the second eyepiece 1220 of the housing cover 1200 remain located on the user's left and right eyes, respectively. When the housing cover 1200 is implemented to be lightweight and compact, the head mounted display 1000 may be provided with, as shown in FIG. 36, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 36 is a perspective view illustrating a head mounted display according to an embodiment.

Referring to FIG. 36, a head mounted display 1000_1 according to an embodiment may be an eyeglasses-type display device in which a display device housing 1200_1 is implemented in a lightweight and compact manner. The head mounted display 1000_1 according to an embodiment may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060, and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 23 illustrates that the display device housing 1200_1 is disposed at the right end portion of the support frame 1030, but embodiments of the present disclosure is not limited thereto. For example, the display device housing 1200_1 may be disposed at the left end portion of the support frame 1030, and in this case, the image of the display device 10_3 may be provided to the user's left eye. Alternatively, the display device housing 1200_1 may be disposed at both the left and right end portions of the support frame 1030, and in this case, the user may view the image displayed on the display device 10_3 through both the left and right eyes.

The display device according to an embodiment can be applied to various electronic devices. The electronic device according to one embodiment includes the display device described above and may further include modules or devices having additional functions in addition to the display device.

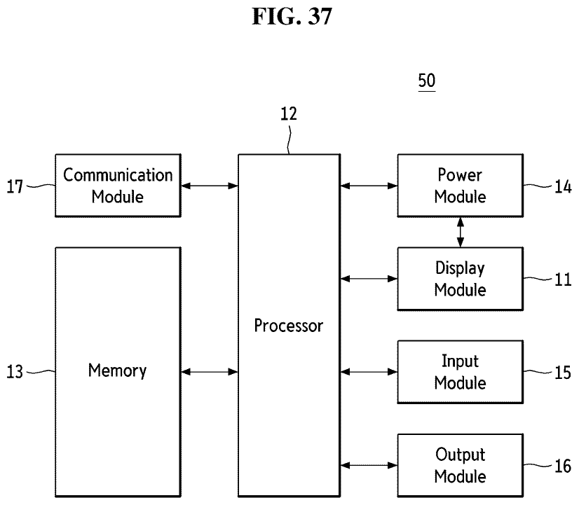

FIG. 37 is a block diagram of an electronic device according to one embodiment. Referring to FIG. 37, the electronic device 50 according to one embodiment may include a display module, a processor 12, a memory 13, and a power module 14. The electronic device 5000 may further include an input module 14, a non-image output module 15 and/or a communication module 16.

The electronic device 50 may output various information in the form of images through the display module 11. When the processor 12 executes an application stored in the memory 13, image information provided by the application may be provided to the user through the display module 1100. The power module 14 may include a power supply module such as a power adapter or a battery device, and a power conversion module that converts the power supplied by the power supply module to generate power required for the operation of the electronic device 5000. The input module 14 may provide input information to the processor 12 and/or the display module 11. The non-image output module 15 may receive information other than images transmitted from the processor 12, such as sound, haptics, and light, and provide the information to the user. The communication module 16 is a module that is responsible for transmitting and receiving information between the electronic device 5000 and an external device, and may include a receiving unit and a transmitting unit.

At least one of the components of the electronic device 50 described above may be included in the display device according to embodiments described above. In addition, some of the individual modules functionally included in one module may be included in the display device, and others may be provided separately from the display device. For example, the display device includes a display module 11, and the processor 12, memory 13, and power module 14 may be provided in the form of other devices within the electronic device 11 other than the display device.

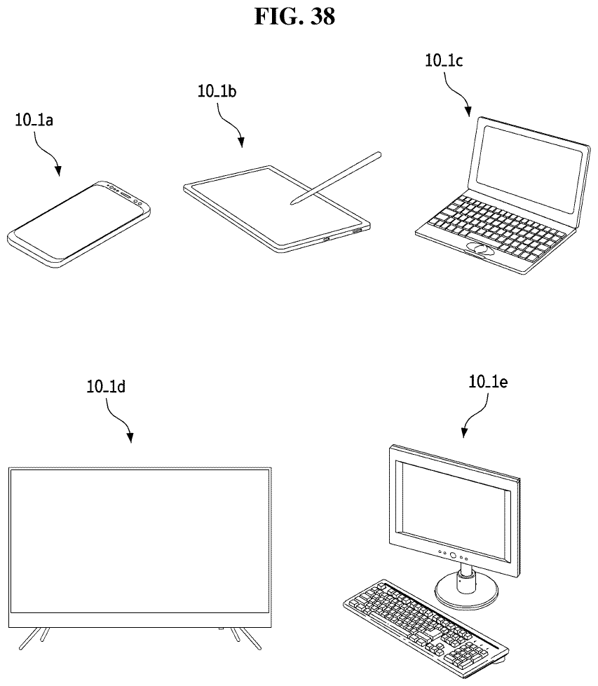

FIGS. 38, 39, and 40 are schematic diagrams of electronic devices according to various embodiments. FIGS. 38 to 40 illustrate examples of various electronic devices to which the display device according to at least some embodiments may be applied.

FIG. 38 illustrates a smartphone 10_1a, a tablet PC 10_1b, a laptop 10_1c, a TV 10_1d, and a desk monitor 10_1e as examples of electronic devices.

In addition to the display module 11, the smartphone 10_1a may include an input module such as a touch sensor and a communication module. The smartphone 10_1a may process information received through the communication module or other input modules and display the information through the display module of the display device.

In the case of tablet PCs 10_1b, laptops 10_1c, TVs 10_1d, and desk monitors 10_1e, they also include display modules and input modules similar to smartphones 10_1, and may additionally include communication modules in some cases.

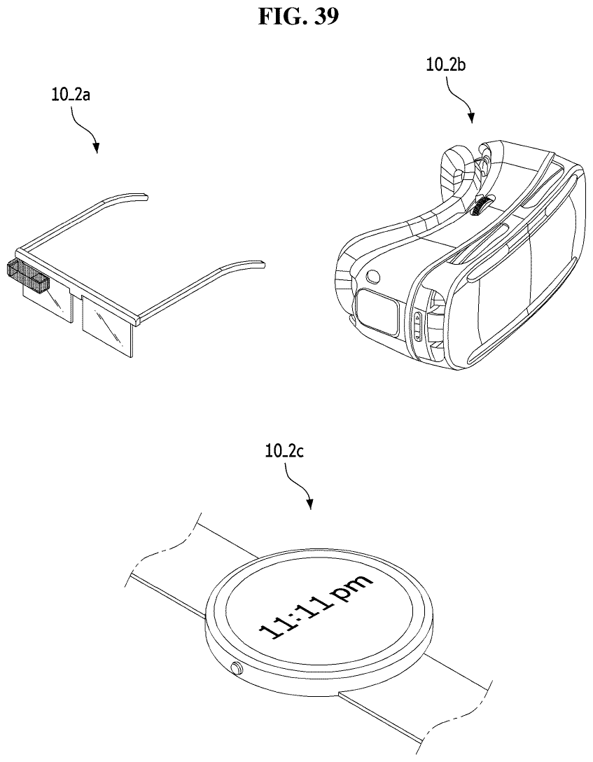

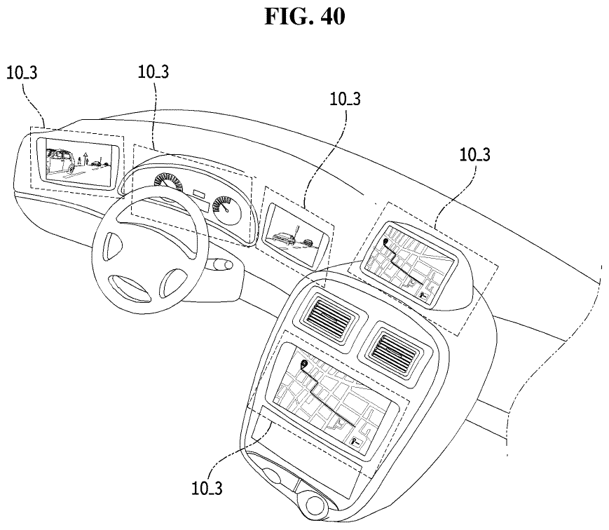

FIG. 39 shows an example of an electronic device including a display module being applied to a wearable electronic device. The wearable electronic device may be a smart glasses 10_2a, a head-mounted display 10_2b, a smart watch 10_2c, etc.

The smart glasses 10_2a and the head-mounted display 10_2b may include a display module that emits a display image and a reflector that reflects the emitted display screen and provides it to the user's eyes, thereby providing a virtual reality or augmented reality screen to the user.

The smart watch 10_2c includes a biometric sensor as an input device, and may provide biometric information recognized by the biometric sensor to the user through the display module. FIG. 40 illustrates a case where an electronic device including a display module is applied to a vehicle. For example, the electronic device 10_3 may be applied to a dashboard, center fascia, etc. of a vehicle, or may be applied to a CID (Center Information Display) placed on a dashboard of a vehicle, or a room mirror display replacing a side mirror.

It will be able to be understood by one of ordinary skill in the art to which the present disclosure belongs that the present disclosure may be implemented in other specific forms without changing the technical spirit or essential features of the present disclosure. Therefore, it is to be understood that exemplary embodiments described herein are illustrative rather than being restrictive in all aspects. It is to be understood that the scope of the present disclosure are defined by the claims rather than the detailed description described above and all modifications and alterations derived from the claims and their equivalents fall within the scope of the present disclosure.

What is claimed is:

1. A display device comprising:
a substrate;
a plurality of electrodes on the substrate;
an insulating film disposed on the plurality of electrodes;
a plurality of contact holes penetrating the insulating film and respectively exposing the plurality of electrodes;
a trench disposed in the insulating film to overlap the plurality of contact holes;
a plurality of connection electrodes respectively connected to the plurality of electrodes through the plurality of contact holes;
a pixel electrode connected to at least one of the plurality of connection electrodes;
a pixel defining film disposed on the pixel electrode and defining an emission area;
a light-emitting layer on the pixel electrode; and
a common electrode on the light-emitting layer.

2. The display device of claim 1, wherein at least one of the plurality of electrodes comprises a source electrode or a drain electrode of a transistor.

3. The display device of claim 1, wherein in plan view, the trench has an inner wall defining a portion of a top surface of the insulating film, the trench surrounds the plurality of contact holes, and the plurality of contact holes extend from the portion of the top surface of the insulating film, wherein inner walls of the plurality of contact holes are spaced apart from the inner wall of the trench.

4. The display device of claim 1, wherein the insulating film has a smaller thickness in a region within the trench than in a region outside the trench.

5. The display device of claim 1, wherein a top surface of the insulating film has a smaller height in a region within the trench than in a region outside the trench.

6. The display device of claim 1, wherein the plurality of connection electrodes extend from a top surface of the insulating film above the trench and through the trench on the top surface of the insulating film within the trench.

7. The display device of claim 1, wherein the plurality of contact holes are arranged in a row.

8. The display device of claim 1, wherein a first inclination angle of an inner wall of the trench, measured from a reference line, and a second inclination angle of an inner wall of at least one of the plurality of contact holes, measured from the reference line, are different from each other.

9. The display device of claim 8, wherein the first inclination angle is greater than the second inclination angle.

10. The display device of claim 1, wherein a depth of at least one of the plurality of contact holes is greater than a depth of the trench.

11. A display device comprising:
a substrate;
a plurality of electrodes on the substrate;
an insulating film disposed on the plurality of electrodes;
a plurality of contact holes penetrating the insulating film and respectively exposing the plurality of electrodes, wherein an inner wall of each contact hole of the plurality of contact holes has a first inclination angle;
a trench disposed in the insulating film to overlap the plurality of contact holes, wherein an inner wall of the trench has a second inclination angle;
a plurality of connection electrodes respectively connected to the plurality of electrodes through the plurality of contact holes; and
a light-emitting element layer disposed on the substrate and connected to at least one of the plurality of connection electrodes.

12. The display device of claim 11, wherein in plan view, the inner wall of the trench defines a portion of a top surface of the insulating film, the trench surrounds the plurality of contact holes, and the plurality of contact holes extend from the portion of the top surface of the insulating film, wherein the inner walls of the plurality of contact holes are spaced apart from the inner wall of the trench.

13. The display device of claim 11, wherein the insulating film has a smaller thickness in a region within the trench than in a region outside the trench.

14. The display device of claim 11, wherein a top surface of the insulating film has a smaller height in a region within the trench than in a region outside the trench.

15. The display device of claim 11, wherein the plurality of connection electrodes extend from a top surface of the insulating film above the trench and through the trench on the top surface of the insulating film within the trench.

16. The display device of claim 11, wherein the plurality of contact holes are arranged in a row.

17. The display device of claim 11, wherein the first inclination angle of the inner walls of the plurality of contact holes, measured from a reference line, and the second inclination angle of the inner wall of the trench, measured from the reference line, are different from each other.

18. The display device of claim 16, wherein the first inclination angle is less than the second inclination angle.

19. The display device of claim 11, wherein a depth of at least one of the plurality of contact holes is greater than a depth of the trench.

20. An electronic device comprising:
a display device including a screen,
wherein the display device comprises:
a substrate;
a plurality of electrodes on the substrate;
an insulating film disposed on the plurality of electrodes;
a plurality of contact holes penetrating the insulating film and respectively exposing the plurality of electrodes;
a trench disposed in the insulating film to overlap the plurality of contact holes;
a plurality of connection electrodes respectively connected to the plurality of electrodes through the plurality of contact holes;
a pixel electrode connected to at least one of the plurality of connection electrodes;
a pixel defining film disposed on the pixel electrode and defining an emission area;
a light-emitting layer on the pixel electrode; and
a common electrode on the light-emitting layer.
